(19) United States
(12) Patent Application Publication
(10) Pub. No.: US 2010/0197051 A1
(43) Pub. Date: Aug. 5, 2010

(54) METROLOGY AND INSPECTION SUITE FOR A SOLAR PRODUCTION LINE

(75) Inventors: Asaf Schlezinger, Sunnyvale, CA (US); Michel R. Frei, Palo Alto, CA (US); Dapeng Wang, Santa Clara, CA (US); Tzay-Fa Su, San Jose, CA (US); Vicky Svidenko, San Jose, CA (US); Kashif Maqsood, San Francisco, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/698,559

(22) Filed: Feb. 2, 2010

Related U.S. Application Data
(60) Provisional application No. 61/149,942, filed on Feb. 4, 2009.
(60) Provisional application No. 61/221,378, filed on Jun. 29, 2009.

(51) Int. Cl. H01L 31/18; H01L 21/66; G06F 17/00

(52) U.S. Cl. 438/16; 700/110; 257/E31.052; 257/E21.529; 700/121

(57) ABSTRACT

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, sectioning, bonding, and various inspection and testing processes to form multiple complete, functional, and tested solar cell devices that can then be shipped to an end user for installation in a desired location to generate electricity. In one embodiment, the system provides inspection of solar cell devices at various levels of formation, while collecting and using metrology data to diagnose, tune, or improve production line processes during the manufacture of solar cell devices.

### CROSS-REFERENCE TO RELATED APPLICATIONS

This application claims benefit of U.S. Provisional Patent Application Ser. No. 61/149,942 [Attorney Docket # APPM 13847L], filed Feb. 4, 2009 and U.S. Provisional Patent Application Ser. No. 61/221,378 [Attorney Docket # 13847L02], filed Jun. 29, 2009, each of which is herein incorporated by reference in its entirety.

### BACKGROUND OF THE INVENTION

1. Field of the Invention

Embodiments of the present invention generally relate to a suite of modules for quality inspection and collection of metrology data during manufacture of a solar cell device in a production line.

2. Description of the Related Art

Photovoltaic (PV) devices or solar cells are devices which convert sunlight into direct current (DC) electrical power. Typical thin film type PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect. Solar cells may be tiled into larger solar arrays. The solar arrays are created by connecting a number of solar cells and joining them into panels with specific frames and connectors.

Typically, a thin film solar cell includes active regions, or photoelectric conversion units, and a transparent conductive oxide (TCO) film disposed as a front electrode and/or as a backside electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers. There is a need for an improved process of forming a solar cell that has good interfacial contact, low contact resistance, and high overall performance.

With traditional energy source prices on the rise, there is a need for a low cost way of producing electricity using a low cost solar cell device. Conventional solar cell manufacturing processes are highly labor intensive and have numerous interruptions that can affect the production line throughput, solar cell cost, and device yield. For instance, conventional quality inspection of solar cell devices is typically either only conducted on fully formed solar cell devices via performance testing or on partially formed solar cell devices that are manually removed from the production line and inspected. Neither inspection scheme provides metrology data to assure the quality of the solar cell devices and diagnose or tune production line processes during manufacturing of the solar cell devices.

Therefore, there is a need for a production line having a suite of modules strategically placed to provide inspection of solar cell devices at various levels of formation, while collecting and using metrology data to diagnose, tune, or improve production line processes during the manufacture of solar cell devices.

### SUMMARY OF THE INVENTION

In one embodiment of the present invention, a solar cell production line comprises a plurality of automation devices configured to serially transfer substrates along a path, a first optical inspection module positioned along the path to receive a substrate having a front contact layer deposited thereon and positioned upstream from one or more cluster tools having at least one processing chamber adapted to deposit a silicon-containing layer on a surface of the substrate, wherein the optical inspection module comprises an inspection device that is positioned to view a region of the substrate and is configured to optically receive information regarding whether defects are present in the viewed region, a film characterization module positioned along the path downstream from the one or more cluster tools and having one or more inspection devices configured to inspect a region of the silicon-containing layer disposed on the surface of the substrate such that information regarding the thickness of the silicon-containing layer can be determined, and a system controller assembly in communication with each of the modules and configured to analyze information received from each of the modules and issue instructions for taking corrective actions to one or more of the modules within the production line.

In another embodiment of the present invention, a solar cell production line comprises a first optical inspection module positioned within the production line upstream from one or more cluster tools having one or more processing chambers adapted to deposit a plurality of silicon-containing layers over the front contact layer and configured to receive a substrate having a front contact layer deposited thereon, wherein the first optical inspection module comprises an inspection device that is positioned to view a region of the substrate and is configured to optically receive information regarding whether defects are present in the viewed region, a second optical inspection module positioned downstream from the one or more cluster tools and configured to receive the substrate having the plurality of silicon-containing layers deposited thereon, wherein the second optical inspection module comprises an inspection device that is positioned to view a region of the substrate and is configured to optically receive information regarding whether a defect in the plurality of silicon-containing layers is present in the viewed region, a plurality of scribe inspection modules, wherein a first of the plurality of scribe inspection modules is positioned downstream from the second optical inspection module and configured to receive the substrate having a plurality of scribed regions formed in the plurality of silicon-containing layers, wherein the first scribe inspection module is configured to optically inspect the scribed regions formed in the plurality of silicon-containing layers, and a system controller assembly in communication with each of the modules and configured to analyze information received from each of the modules and issue instructions for taking corrective actions to one or more of the modules within the production line.

In another embodiment of the present invention, a method of forming solar cells in a production line comprises serially transferring a plurality of substrates along a transfer path using a plurality of automation devices, processing each of the plurality of substrates in a plurality of processing modules disposed along the transfer path, and inspecting each of the plurality of substrates in a plurality of inspection modules which are disposed along the transfer path. In one embodiment, processing each of the plurality of substrates comprises removing a portion of a front contact layer deposited on a surface of each substrate in a first processing module positioned along the transfer path, depositing a first plurality of silicon-containing layers over the front contact layer in a first cluster tool within a second processing module positioned downstream from the first processing module along the transfer path, removing a portion of the plurality of silicon-containing layers in a third processing module positioned downstream from the second processing module along the transfer path, depositing a metal layer over the plurality of silicon-containing layers in a fourth processing module positioned downstream from the third processing module along the transfer path, and removing a portion of the metal layer in a fifth processing module positioned downstream from the fourth processing module to form at least two serially connected solar cells on each substrate. In one embodiment, inspecting each of the plurality of substrates comprises optically inspecting a region of each substrate in a first inspection module positioned upstream from the second processing module and determining whether a defect exists within the region, measuring electrical continuity between portions of the front contact layer disposed on opposite sides of the removed portion of the front contact layer in a second inspection module positioned upstream from the second processing module, inspecting the first plurality of silicon-containing layers on each substrate in a third inspection module positioned downstream from the first cluster tool and determining the thickness of at least one of the first plurality of silicon-containing layers, optically inspecting a region of at least the first plurality of silicon-containing layers of each substrate in a fourth inspection module positioned downstream from the second processing module and determining whether a defect exists in the plurality of silicon-containing layers within the region, optically inspecting a region of each substrate where at least a portion of at least the first plurality of silicon-containing layers has been removed in a fifth inspection module positioned downstream from the third processing module, and optically inspecting a region of each substrate where at least a portion of the metal layer has been removed in a sixth inspection module positioned downstream from the fifth processing module.

In yet another embodiment of the present invention, a solar cell production line comprises a plurality of automation devices which are configured to serially transfer substrates along a path, a first scribe module positioned along the path to receive a substrate having a front contact layer deposited thereon and configured to form a plurality of scribed regions in the front contact layer, a first cluster tool positioned along the path downstream from the first scribe module and having one or more processing chambers configured to deposit a first plurality of silicon-containing layers over the front contact layer, a first film characterization module positioned along the path downstream from the first cluster tool and having one or more inspection devices configured to inspect a region of the first silicon-containing layers disposed on the surface of each substrate such that information regarding the thickness of at least one of the first plurality of silicon-containing layers can be determined, a second cluster tool positioned along the path downstream from the first film characterization module and having one or more processing chambers configured to deposit a second plurality of silicon-containing layers over the first plurality of silicon-containing layers, a second film characterization module positioned along the path downstream from the second cluster tool and having one or more inspection devices configured to inspect a region of the second silicon-containing layers disposed on the surface of each substrate such that information regarding the thickness of at least one of the second plurality of silicon-containing layers can be determined, and a system controller assembly in communication with the first and second film characterization modules and configured to analyze information received from each of the first and second film characterization modules and issue instructions for taking corrective actions to one or more of the modules within the production line.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device according to one embodiment described herein.

FIG. 2 illustrates a plan view of a solar cell production line according to one embodiment described herein.

FIG. 3A is a side cross-sectional view of a thin film solar cell device according to one embodiment described herein.

FIG. 3B is a side cross-sectional view of a thin film solar cell device according to one embodiment described herein.

FIG. 3C is a plan view of a composite solar cell structure according to one embodiment described herein.

FIG. 3D is a side cross-sectional view along Section A-A of FIG. 3C.

FIG. 3E is a side cross-sectional view of a thin film solar cell device according to one embodiment described herein.

FIG. 3F is a schematic, isometric, partial view of a device substrate being electrically inspected by an electrical inspection module according to one embodiment described herein.

FIG. 3G is a schematic, cross-sectional view of a portion of a particular device substrate being inspected in an inspection module.

FIG. 3H is a schematic, cross-sectional, partial view of a device substrate being electrically inspected by a quality assurance module according to one embodiment described herein.

FIG. 3I is a schematic, partial, plan view of a depiction of a device substrate having defects mapped thereon.

FIG. 4 is an isometric view of an optical inspection module according to one embodiment described herein.

FIG. 5 is a schematic view of one embodiment of the various control features that may be contained within the system controller.

### DETAILED DESCRIPTION

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, sectioning, bonding, and various inspection and testing processes to form multiple complete, functional, and tested solar cell devices that can then be shipped to an end user for installation in a desired location to generate electricity. In one embodiment, the system provides inspection of solar cell devices at various levels of formation, while collecting and using metrology data to diagnose, tune, or improve production line processes during the manufacture of solar cell devices. While the discussion below primarily describes the formation of silicon thin film solar cell devices, this configuration is not intended to be limiting as to the scope of the invention since the apparatus and methods disclosed herein can also be used to form, test, and analyze other types of solar cell devices, such as III-V type solar cells, thin film chalcogenide solar cells (e.g., CIGS, CdTe cells), amorphous or nanocrystalline silicon solar cells, photochemical type solar cells (e.g., dye sensitized), crystalline silicon solar cells, organic type solar cells, or other similar solar cell devices.

The system is generally an arrangement of automated processing modules and automation equipment used to form solar cell devices that are interconnected by an automated material handling system. In one embodiment, the system is a fully automated solar cell device production line that reduces or removes the need for human interaction and/or labor intensive processing steps to improve the solar cell device reliability, production process repeatability, and the cost of ownership of the solar cell device formation process. In one configuration, the system generally comprises a substrate receiving module that is adapted to accept an incoming substrate, one or more absorbing layer deposition cluster tools having at least one processing chamber that is adapted to deposit a silicon-containing layer on a processing surface of the substrate, one or more back contact deposition chambers that is adapted to deposit a back contact layer on the processing surface of the substrate, one or more material removal chambers that are adapted to remove material from the processing surface of each substrate, one or more sectioning modules used to section the processed substrate into multiple smaller processed substrates, a solar cell encapsulation device, an autoclave module that is adapted to heat and expose a composite solar cell structure to a pressure greater than atmospheric pressure, a junction box attaching region to attach a connection element that allows the solar cells to be connected to external components, a suite of inspection modules adapted to inspect each solar cell device at various levels of formation, and one or more quality assurance modules adapted to test and qualify each completely formed solar cell device. In one embodiment, the suite of inspection modules includes one or more optical inspection modules and electrical inspection modules configured to collect metrology data and communicate the data to a system controller to diagnose, tune, improve, and/or assure quality processing within the solar cell device production system.

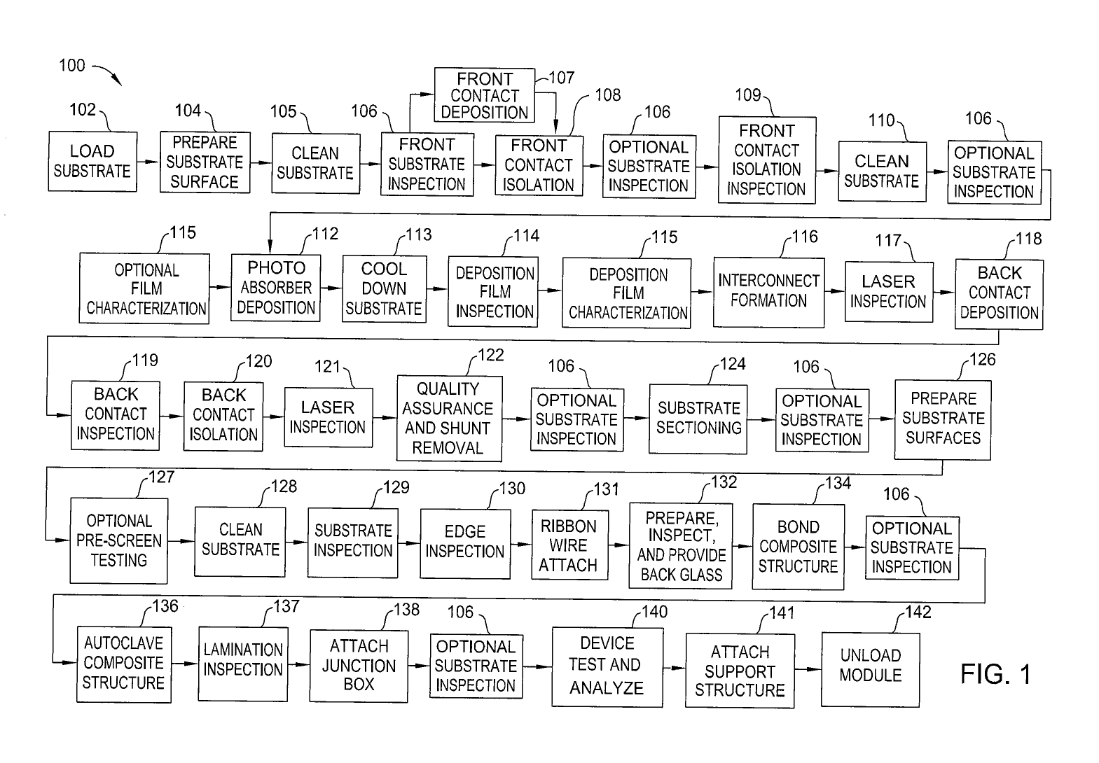

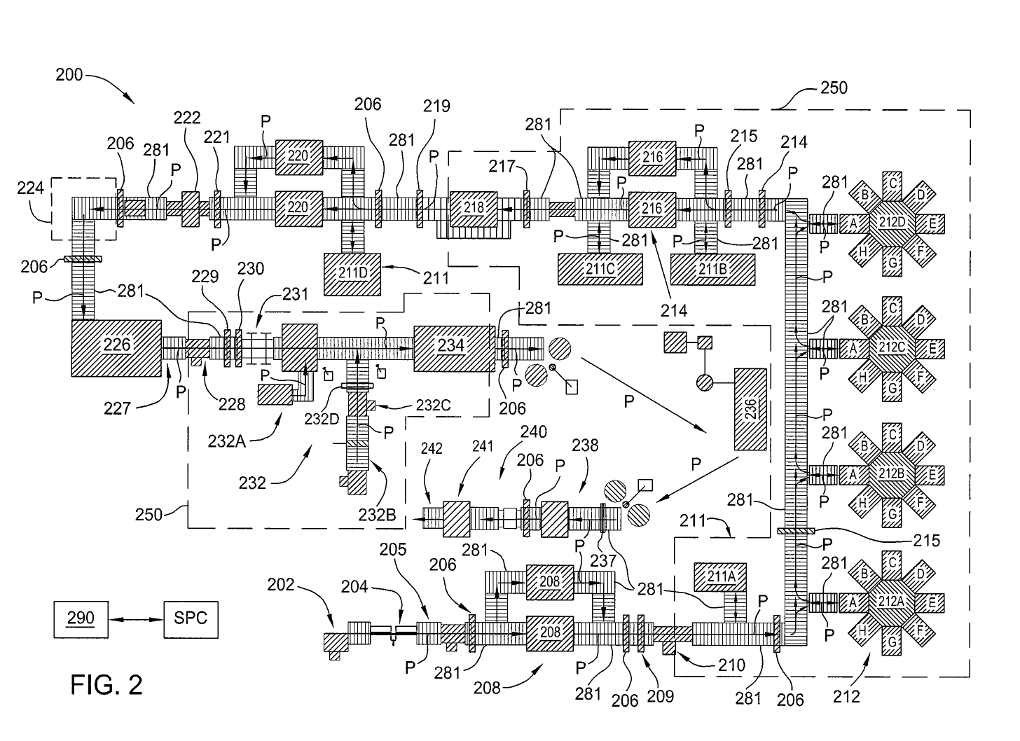

FIG. 1 illustrates one embodiment of a process sequence 100 that contains a plurality of steps (i.e., steps 102-142) that are each used to form a solar cell device using a novel solar cell production line 200 described herein. The configuration, number of processing steps, and order of the processing steps in the process sequence 100 is not intended to be limiting to the scope of the invention described herein. FIG. 2 is a plan view of one embodiment of the production line 200, which is intended to illustrate some of the typical processing modules and process flows through the system and other related aspects of the system design, and is thus not intended to be limiting to the scope of the invention described herein.

In general, a system controller 290 may be used to control one or more components found in the solar cell production line 200. The system controller 290 is generally designed to facilitate the control and automation of the overall solar cell production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the solar cell production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete solar cell production line. In one embodiment, the system controller includes local controllers disposed in inspection modules to map and evaluate defects detected in each substrate as it passes through the production line 200 and determine whether to allow the substrate to proceed or reject the substrate for corrective processing or scrapping. An example of a system controller, distributed control architecture, and other system control structure that may be useful for one or more of the embodiments described herein can be found in the U.S. patent application Ser. No. 12/202,199 [Atty. Dkt. No. 11141], which is incorporated by reference.

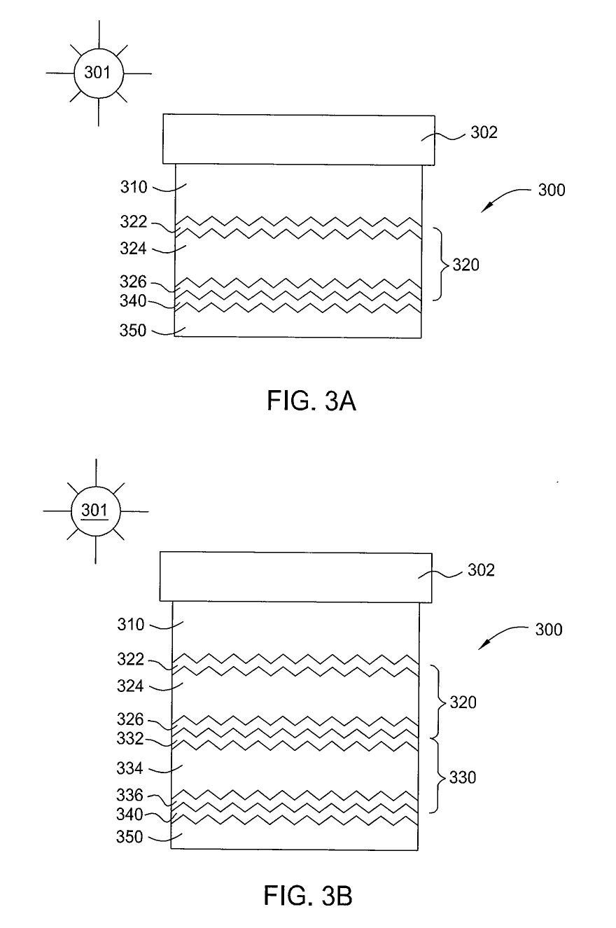

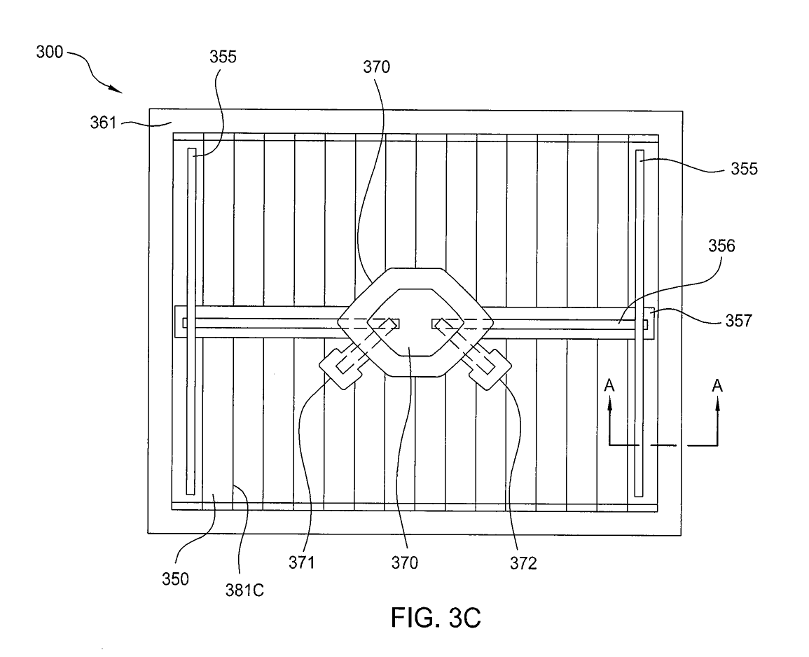

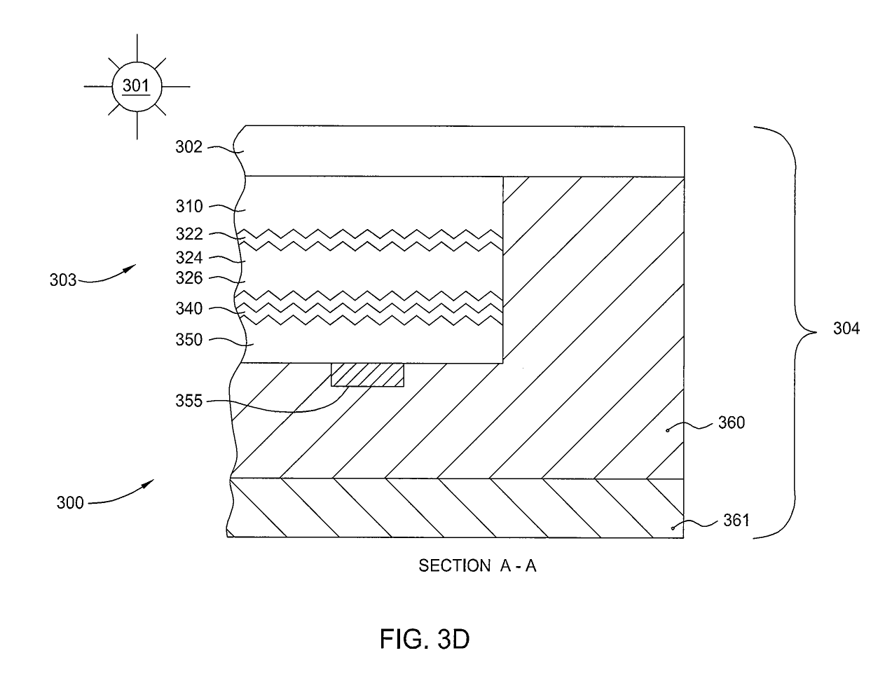

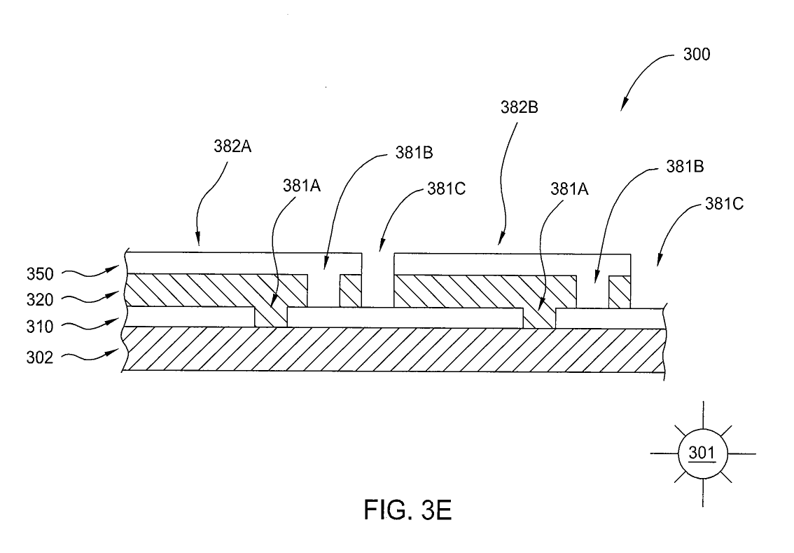

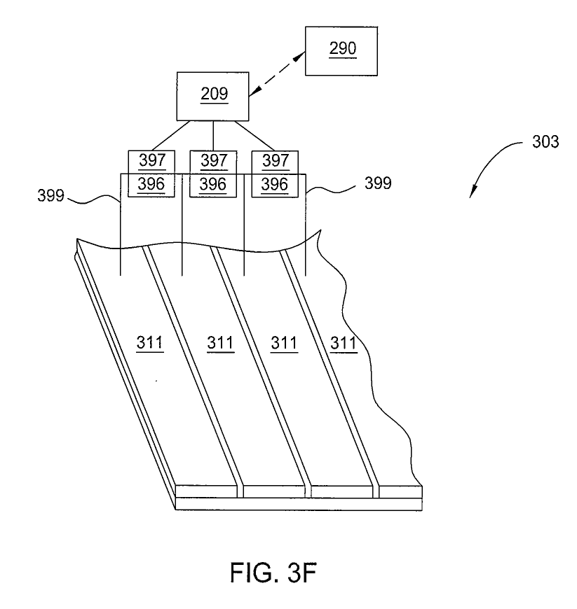

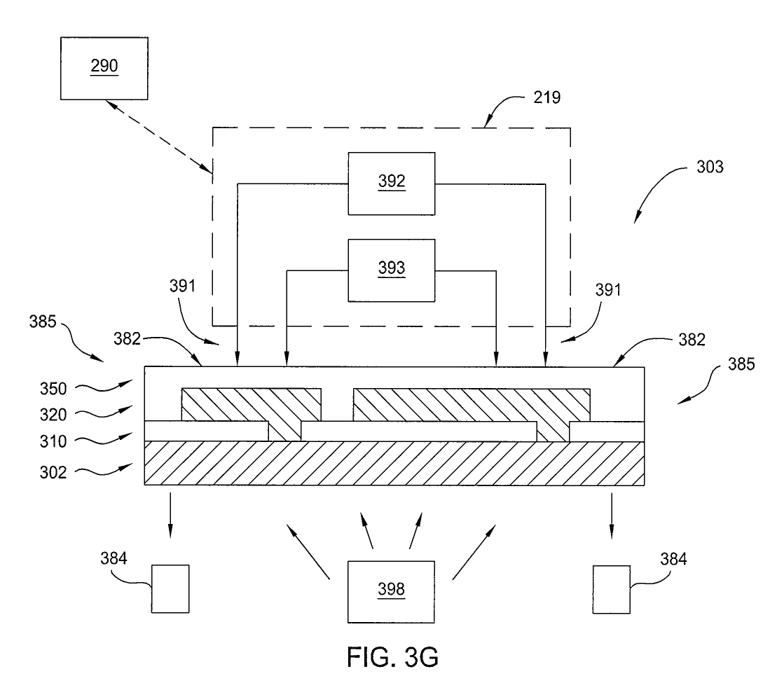

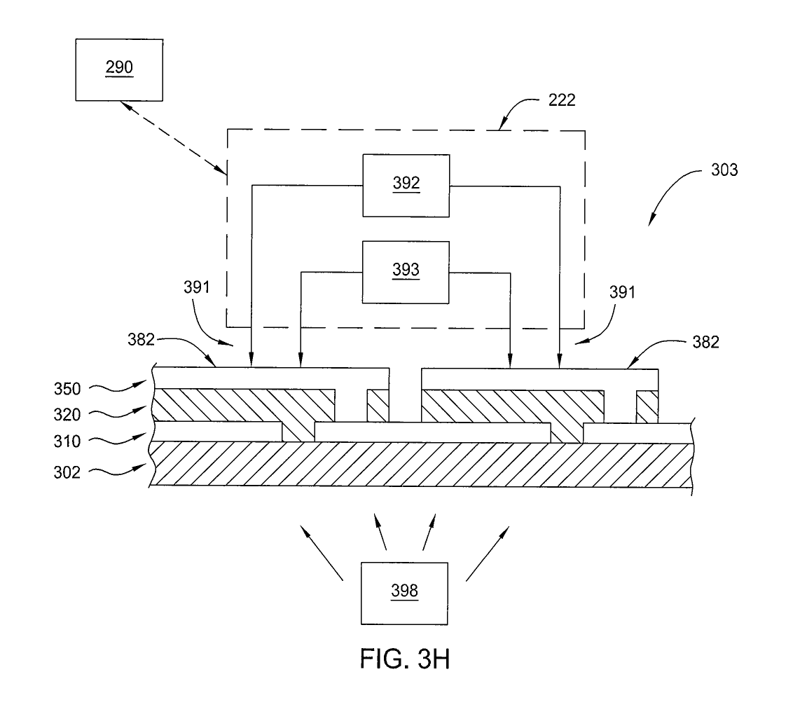

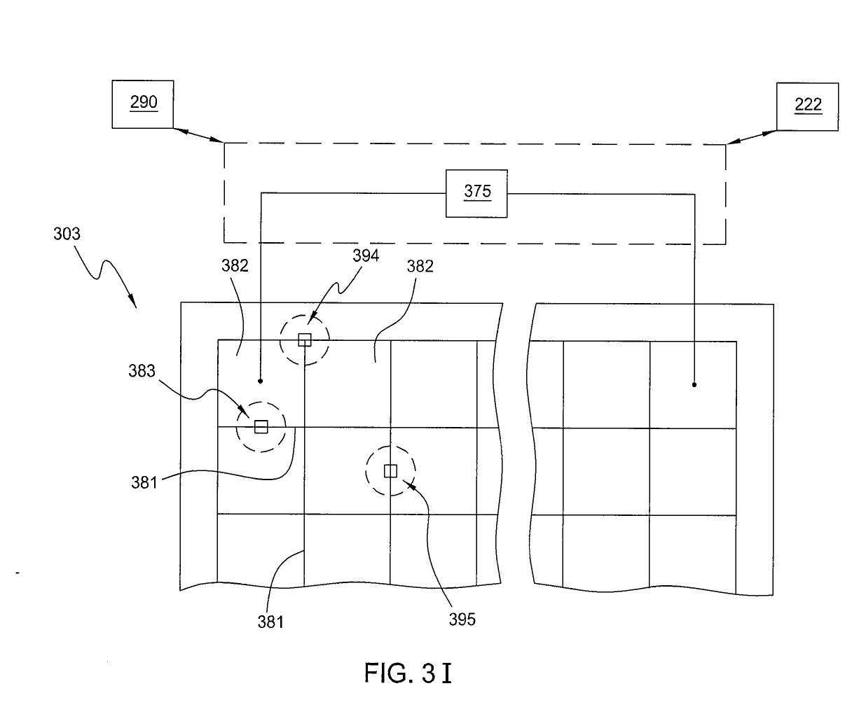

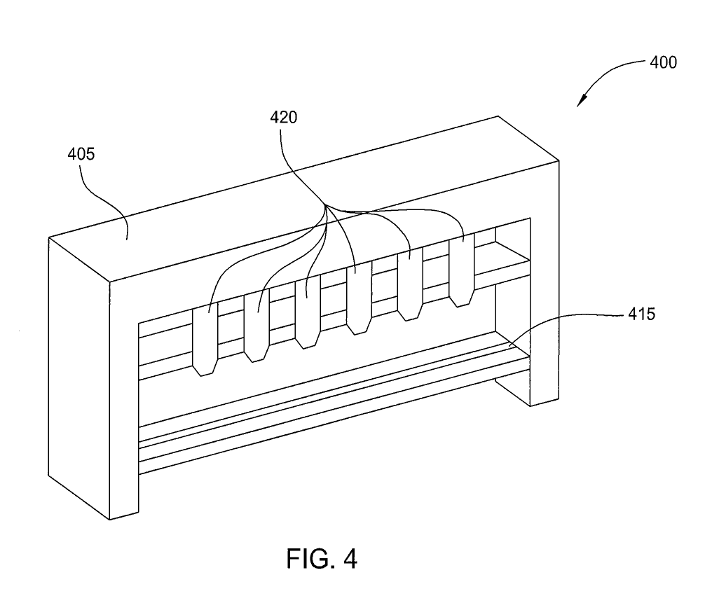

Examples of a solar cell 300 that can be formed using the process sequence(s) illustrated in FIG. 1 and the components illustrated in the solar cell production line 200 are illustrated in FIGS. 3A-3E. FIG. 3A is a simplified schematic diagram of a single junction amorphous or micro-crystalline silicon solar cell 300 that can be formed and analyzed in the system described below. As shown in FIG. 3A, the single junction amorphous or micro-crystalline silicon solar cell 300 is oriented toward a light source or solar radiation 301. The solar cell 300 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 300 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it. In one configuration, the first p-i-n junction 320 may comprise a p-type amorphous silicon layer 322, an intrinsic type amorphous silicon layer 324 formed over the p-type amorphous silicon layer 322, and an n-type amorphous silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type amorphous semiconductor layer 326 may be formed to a thickness between about 100 Å and about 500 Å. The back contact layer 350 may include, but is not limited to a material selected from the group consisting of Al, Ag, Ti, Cr, Au, Cu, Pt, alloys thereof, and combinations thereof.

FIG. 3B is a schematic diagram of an embodiment of a solar cell 300, which is a multi-junction solar cell that is oriented toward the light or solar radiation 301. The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340. In the embodiment shown in FIG. 3B, the first TCO layer 310 is textured, and the subsequent thin films deposited thereover generally follow the topography of the surface below it. The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline semiconductor layer 326 may be formed to a thickness between about 100 Å and about 400 Å. The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to a material selected from the group consisting of Al, Ag, Ti, Cr, Au, Cu, Pt, alloys thereof, and combinations thereof.

FIG. 3C is a plan view that schematically illustrates an example of the rear surface of a formed solar cell 300 that has been produced in the production line 200. FIG. 3D is a side cross-sectional view of portion of the solar cell 300 illustrated in FIG. 3C (see section A-A). While FIG. 3D illustrates the cross-section of a single junction cell similar to the configuration described in FIG. 3A, this is not intended to be limiting as to the scope of the invention described herein.

As shown in FIGS. 3C and 3D, the solar cell 300 may contain a substrate 302, the solar cell device elements (e.g., reference numerals 310-350), one or more internal electrical connections (e.g., side buss 355, cross-buss 356), a layer of bonding material 360, a back glass substrate 361, and a junction box 370. The junction box 370 may generally contain two connection points 371, 372 that are electrically connected to portions of the solar cell 300 through the side buss 355 and the cross-buss 356, which are in electrical communication with the back contact layer 350 and active regions of the solar cell 300. To avoid confusion relating to the actions specifically performed on the substrates 302 in the discussion below, a substrate 302 having one or more of the deposited layers (e.g., reference numerals 310-350) and/or one or more internal electrical connections (e.g., side buss 355, cross-buss 356) disposed thereon is generally referred to as a device substrate 303. Similarly, a device substrate 303 that has been bonded to a back glass substrate 361 using a layer of bonding material 360 is referred to as a composite solar cell structure 304.

FIG. 3E is a schematic cross-section of a solar cell 300 illustrating various scribed regions used to form the individual cells 382A-382B within the solar cell 300. As illustrated in FIG. 3E, the solar cell 300 includes a transparent substrate 302, a first TCO layer 310, a first p-i-n junction 320, and a back contact layer 350. Three laser scribing steps may be performed to produce trenches 381A, 381B, and 381C, which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. While a single junction type solar cell is illustrated in FIG. 3E this configuration is not intended to be limiting to the scope of the invention described herein.

### General Solar Cell Formation Process Sequence

Referring to FIGS. 1 and 2, the process sequence 100 generally starts at step 102 in which a substrate 302 is loaded into the loading module 202 found in the solar cell production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., first TCO layer 310) already deposited on a surface of the substrate 302 before it is received into the system in step 102. If a conductive layer, such as TCO layer, is not deposited on the surface of the “raw” substrates then a front contact deposition step (step 107), which is discussed below, needs to be performed on a surface of the substrate 302.

In one embodiment, the substrates 302 or 303 are loaded into the solar cell production line 200 in a sequential fashion, and thus do not use a cassette or batch style substrate loading system. A cassette style and/or batch loading type system that requires the substrates to be un-loaded from the cassette, processed, and then returned to the cassette before moving to the next step in the process sequence can be time consuming and decrease the solar cell production line throughput. The use of batch processing does not facilitate certain embodiments of the present invention, such as fabricating multiple solar cell devices from a single substrate. Additionally, the use of a batch style process sequence generally prevents the use of an asynchronous flow of substrates through the production line, which is believed to provide improved substrate throughput during steady state processing and when one or more modules are brought down for maintenance or due to a fault condition. Generally, batch or cassette based schemes are not able to achieve the throughput of the production line described herein, when one or more processing modules are brought down for maintenance, or even during normal operation, since the queuing and loading of substrates can require a significant amount of overhead time.

In the next step, step 104, the surfaces of the substrate 302 are prepared to prevent yield issues later on in the process. In one embodiment of step 104, the substrate is inserted into a front end substrate seaming module 204 that is used to prepare the edges of the substrate 302 or 303 to reduce the likelihood of damage, such as chipping or particle generation from occurring during the subsequent processes. Damage to the substrate 302 or 303 can affect device yield and the cost to produce a usable solar cell device. In one embodiment, the front end seaming module 204 is used to round or bevel the edges of the substrate 302 or 303. In one embodiment, a diamond impregnated belt or disc is used to grind the material from the edges of the substrate 302 or 303. In another embodiment, a grinding wheel, grit blasting, or laser ablation technique is used to remove the material from the edges of the substrate 302 or 303.

Next the substrate 302 or 303 is transported to the cleaning module 205, in which step 105, or a substrate cleaning step, is performed on the substrate 302 or 303 to remove any contaminants found on the surface of thereof. Common contaminants may include materials deposited on the substrate 302 or 303 during the substrate forming process (e.g., glass manufacturing process) and/or during shipping or storing of the substrates 302 or 303. Typically, the cleaning module 205 uses wet chemical scrubbing and rinsing steps to remove any undesirable contaminants.

In one example, the process of cleaning the substrate 302 or 303 may occur as follows. First, the substrate 302 or 303 enters a contaminant removal section of the cleaning module 205 from either a transfer table or an automation device 281. In general, the system controller 290 establishes the timing for each substrate 302 or 303 that enters the cleaning module 205. The contaminant removal section may utilize dry cylindrical brushes in conjunction with a vacuum system to dislodge and extract contaminants from the surface of the substrate 302. Next, a conveyor within the cleaning module 205 transfers the substrate 302 or 303 to a pre-rinse section, where spray tubes dispense hot DI water at a temperature, for example, of 50° C. from a DI water heater onto a surface of the substrate 302 or 303. Commonly, since the device substrate 303 has a TCO layer disposed thereon, and since TCO layers are generally electron absorbing materials, DI water is used to avoid any traces of possible contamination and ionizing of the TCO layer. Next, the rinsed substrate 302, 303 enters a wash section. In the wash section, the substrate 302 or 303 is wet-cleaned with a brush (e.g., perlon) and hot water. In some cases a detergent (e.g., Alconox™, Citrajet™, Detojet™, Transene™, and Basic H™) surfactant, pH adjusting agent, and other cleaning chemistries are used to clean and remove unwanted contaminants and particles from the substrate surface. A water re-circulation system recycles the hot water flow. Next, in a final rinse section of the cleaning module 205, the substrate 302 or 303 is rinsed with water at ambient temperature to remove any traces of contaminants. Finally, in a drying section, an air blower is used to dry the substrate 302 or 303 with hot air. In one configuration a deionization bar is used to remove the electrical charge from the substrate 302 or 303 at the completion of the drying process.

In the next step, or front substrate inspection step 106, the substrate 302 or 303 is inspected via an inspection module 206, and metrology data is collected and sent to the system controller 290. In one embodiment, the substrate 302 or 303 is optically inspected for defects, such as chips, cracks, inclusions, bubbles, or scratches that may inhibit performance of a fully formed solar cell device, such as the solar cell 300. In one embodiment, the optical characteristics of the substrate 302 are inspected via the inspection module 206 and metrology data is collected and sent to the system controller 290 for analysis and storage. In one embodiment, the optical characteristics of the TCO layer of the device substrate 303 is inspected by the inspection module 206 and metrology data is collected and sent to the system controller 290 for analysis and storage.

In one embodiment, the substrate 302, 303 is passed through the inspection module 206 via the automation device 281. In one embodiment of the front substrate inspection step 106, as the substrate 302, 303 passes through the inspection module 206, the substrate 302, 303 is optically inspected, and images of the substrate 302, 303 are captured and sent to the system controller 290, where the images are analyzed and metrology data is collected and stored in memory.

In one embodiment, the images captured by the inspection module 206 are analyzed by the system controller 290 to determine whether the substrate 302, 303 meets specified quality criteria. If the specified quality criteria are met, the substrate 302, 303 continues on its path in the system 200. However, if the specified criteria are not met, actions may be taken to either repair the defect or reject the defective substrate 302, 303. In one embodiment, defects detected in the substrate 302, 303 are mapped and analyzed in a portion of the system controller 290 disposed locally within the inspection module 206. In this embodiment, the decision to reject a particular substrate 302, 303 may be made locally within the inspection module 206.

In one embodiment, the system controller 290 may compare information regarding the size of a crack on an edge of a substrate 302, 303 with a specified allowable crack length to determine whether the substrate 302, 303 is acceptable for continued processing in the system 200. In one embodiment, a crack of about 1 mm or smaller is acceptable. Other criteria that the system controller may compare include the size of a chip in the edge of the substrate 302, 303 or the size of an inclusion or bubble in the substrate 302, 303. In one embodiment, a chip of about 5 mm or less may be acceptable, and an inclusion or bubble of less than about 1 mm may be acceptable. In determining whether to allow continued processing or reject each particular substrate 302, 303, the system controller may apply a weighting scheme to the defects mapped in particular regions of the substrate. For instance, defects detected in critical areas, such as edge regions of the substrate 302, 303, may be given significantly greater weighting than defects found in less critical areas.

In one embodiment, the TCO layer of the device substrate 303 is inspected via the inspection module 206. The optical characteristics of the TCO layer, e.g. optical transmission and haze, may be detected and captured via the inspection module 206.

In one embodiment, the system controller 290 collects and analyzes the metrology data received from the inspection module 206 for use in determining the root cause of recurring defects in the substrate 302, 303 so that it can correct or tune the preceding processes to eliminate the recurring defects. In one embodiment, the system controller 290 locally maps the defects detected in each substrate 302, 303 for use in a manual or automated metrology data analysis performed by the user or system controller 290. In one embodiment, the optical characteristics of each device substrate 303 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

One embodiment of an optical inspection module, such as the inspection module 206, is subsequently described in the “Optical Inspection Module” section below. Although the inspection module 206 is first depicted and discussed immediately downstream from the cleaning module 205, the optical inspection module 206 (and the corresponding inspection step 106) may also be provided at various other locations through the production line 200, as subsequently mentioned in the following description. In general, the inspection module 206 (and corresponding inspection step 106) may be provided following each mechanical handling module located within the production line 200 in order to detect any physical damage to the substrate 302, device substrate 303, or composite solar cell structure 304. The metrology data extracted from any or all of the inspection modules 206 may be analyzed and used by the system controller 290 to diagnose trends and take any necessary corrective actions.

In the next step, or step 108, separate cells are electrically isolated from one another via scribing processes. Contamination particles on the TCO surface and/or on the bare glass surface can interfere with the scribing procedure. In laser scribing, for example, if the laser beam runs across a particle, it may be unable to scribe a continuous line, and a short circuit between cells will result. In addition, any particulate debris present in the scribed pattern and/or on the TCO of the cells after scribing can cause shunting and non-uniformities between layers. Therefore, a well-defined and well-maintained process is generally needed to ensure that contamination is removed throughout the production process. In one embodiment, the cleaning module 205 is available from the Energy and Environment Solutions division of Applied Materials in Santa Clara, Calif.

Referring to FIGS. 1 and 2, in one embodiment, prior to performing step 108 the substrates 302 are transported to a front end processing module (not illustrated in FIG. 2) in which a front contact formation process, or step 107, is performed on the substrate 302. In one embodiment, the front end processing module is similar to the processing module 218 discussed below. In step 107, the one or more substrate front contact formation steps may include one or more preparation, etching and/or material deposition steps that are used to form the front contact regions on a bare solar cell substrate 302. In one embodiment, step 107 generally comprises one or more PVD steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more CVD steps are used to form the front contact region on a surface of the substrate 302.

Next the device substrate 303 is transported to the scribe module 208 in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process. The success criteria for step 108 are to achieve good cell-to-cell and cell-to-edge isolation while minimizing the scribe area. In one embodiment, a Nd:vanadate (Nd:YVO₄) laser source is used ablate material from the device substrate 303 surface to form lines that electrically isolate one region of the device substrate 303 from the next. In one embodiment, the laser scribe process performed during step 108 uses a 1064 nm wavelength pulsed laser to pattern the material disposed on the substrate 302 to isolate each of the individual cells (e.g., reference numbers 382A and 382B (FIG. 3E)) that make up the solar cell 300. In one embodiment, a 5.7 m² substrate laser scribe module available from Applied Materials, Inc. of Santa Clara, Calif. is used to provide simple reliable optics and substrate motion for accurate electrical isolation of regions of the device substrate 303 surface. In another embodiment, a water jet cutting tool or diamond scribe is used to isolate the various regions on the surface of the device substrate 303. In one aspect, it is desirable to assure that the temperature of the device substrates 303 entering the scribe module 208 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the device substrate 303 temperature to about 25+/−0.5° C.

In one embodiment, the device substrate 303 may be optionally transferred into another inspection module 206, where a corresponding inspection step 106 may be performed on the device substrate 303 to detect any damage caused by handling devices within the scribe module 208. In one embodiment, the substrate 303 is passed through the inspection module 206 via the automation device 281. In one embodiment of the front substrate inspection step 106, as the substrate 303 passes through the inspection module 206, the substrate 303 is optically inspected, and images of the substrate 303 are captured and sent to the system controller 290, where the images are analyzed and metrology data is collected and stored in memory.

In one embodiment, the images captured by the inspection module 206 are analyzed by the system controller 290 to determine whether the substrate 303 meets specified quality criteria. If the specified quality criteria are met, the substrate 303 continues on its path in the system 200. However, if the specified criteria are not met, actions may be taken to either repair the defect or reject the defective substrate 303. In one embodiment, defects detected in the substrate 303 are mapped and analyzed in a portion of the system controller 290 disposed locally within the inspection module 206. In this embodiment, the decision to reject a particular substrate 303 may be made locally within the inspection module 206.

In one embodiment, the system controller 290 may compare information regarding the size of a crack on an edge of a substrate 303 with a specified allowable crack length to determine whether the substrate 303 is acceptable for continued processing in the system 200. In one embodiment, a crack of about 1 mm or smaller is acceptable. Other criteria that the system controller may compare include the size of a chip in the edge of the substrate 303 or the size of an inclusion or bubble in the substrate 303. In one embodiment, a chip of about 5 mm or less may be acceptable, and an inclusion or bubble of less than about 1 mm may be acceptable. In determining whether to allow continued processing or reject each particular substrate 303, the system controller may apply a weighting scheme to the defects mapped in particular regions of the substrate. For instance, defects detected in critical areas, such as edge regions of the substrate 303, may be given significantly greater weighting than defects found in less critical areas.

In one embodiment, the system controller 290 collects and analyzes the metrology data received from the inspection module 206 for use in determining the root cause of recurring defects in the substrate 303 so that it can correct or tune the preceding processes to eliminate the recurring defects. In one embodiment, the system controller 290 locally maps the defects detected in each substrate 303 for use in a manual or automated metrology data analysis performed by the user or system controller 290. In one embodiment, the optical characteristics of each device substrate 303 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next, the device substrate 303 is transported to an inspection module 209 in which a front contact isolation inspection step 109 is performed on the device substrate 303 to assure the quality of the front contact isolation step 108. The collected metrology data is then sent and stored within the system controller 290. FIG. 3F is schematic, isometric view of a portion of a device substrate 303 being inspected by the inspection module 209 according to one embodiment of the present invention. In one embodiment, the inspection module 209 probes each individual cell 311 of the device substrate 303 to measure whether a conductive path, or continuity, exists in the isolation area between adjacent cells 311.

In one embodiment, the device substrate 303 is passed through the inspection module 209 via the automation device 281. As the device substrate 303 passes through the inspection module 209, electrical continuity between each pair of adjacent cells 311 is measured via probes 391 as shown in FIG. 3F. In one embodiment, a voltage is applied between adjacent cells 311 on the device substrate 303 via a voltage source 397, and a resistance between probes 391 that are in contact with the adjacent cells 311 is measured via a measurement device 396. If the measurement exceeds a specified criterion, such as about 1 MO, an instruction may be sent that no continuity exists between the probed cells. If the measurement is less than a specified criterion, such as about 6 kΩ, an instruction may be sent that continuity, or a short, exists between the probed cells. The information regarding continuity of the cells may be transmitted to the system controller 290, where the data is collected, analyzed, and stored.

In one embodiment, the information captured by the inspection module 209 is analyzed by the system controller 290 to determine whether the device substrate 303 meets specified quality criteria. If the specified quality criteria are met, the device substrate 303 continues on its path in the system 200. However, if the specified criteria are not met, actions may be taken to either repair the defect or reject the defective device substrate 303. In one embodiment, defects detected in the device substrate 303 are captured and analyzed in a portion of the system controller 290 disposed locally within the inspection module 209. In this embodiment, the decision to reject a particular device substrate 303 may be made locally within the inspection module 209.

In one embodiment, if the information provided to the system controller 290 from the inspection module 209 indicates continuity between two adjacent cells, the device substrate 303 may be rejected and sent back through the scribe module 208 for corrective action. In one embodiment, the inspection module 209 may be incorporated within the scribe module 208 so that any areas of continuity between adjacent cells may be discovered and corrected before leaving the scribe module 208.

In one embodiment, a voltage is individually applied across one or more cells 311 on the device substrate 303 via the voltage source 397, and a resistance between probes 391 that are in contact with the cell 311 is measured via a measurement device 396. Thus, the sheet resistance of the TCO layer on the device substrate 303 may be determined at various locations on the device substrate.

In one embodiment, the system controller 290 collects and analyzes the metrology data received from the inspection module 209 for use in determining the root cause of recurring defects in the device substrate 303 and correcting or tuning the front contact isolation step 108 or other preceding processes, such as the substrate cleaning step 105, to eliminate the recurring defects. In one embodiment, the system controller 290 uses the collected data to map the defects detected in each device substrate 303 for use in metrology data analysis. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next the device substrate 303 is transported to the cleaning module 210 in which step 110, or a pre-deposition substrate cleaning step, is performed on the device substrate 303 to remove any contaminants found on the surface of the device substrate 303 after performing the cell isolation step 108. Typically, the cleaning module 210 uses wet chemical scrubbing and rinsing steps to remove any undesirable contaminants found on the device substrate 303 surface after performing the cell isolation step. In one embodiment, a cleaning process similar to the processes described in step 105 above is performed on the device substrate 303 to remove any contaminants on the surface(s) of the device substrate 303.

In one embodiment, the device substrate 303 may be optionally transferred into another inspection module 206, where a corresponding inspection step 106 may be performed on the device substrate 303 to detect any damage caused by handling devices within the scribe module 208. In one embodiment, the substrate 303 is passed through the inspection module 206 via the automation device 281. In one embodiment of the front substrate inspection step 106, as the substrate 303 passes through the inspection module 206, the substrate 303 is optically inspected, and images of the substrate 303 are captured and sent to the system controller 290, where the images are analyzed and metrology data is collected and stored in memory.

In one embodiment, the images captured by the inspection module 206 are analyzed by the system controller 290 to determine whether the substrate 303 meets specified quality criteria. If the specified quality criteria are met, the substrate 303 continues on its path in the system 200. However, if the specified criteria are not met, actions may be taken to either repair the defect or reject the defective substrate 303. In one embodiment, defects detected in the substrate 303 are mapped and analyzed in a portion of the system controller 290 disposed locally within the inspection module 206. In this embodiment, the decision to reject a particular substrate 303 may be made locally within the inspection module 206.

In one embodiment, the system controller 290 may compare information regarding the size of a crack on an edge of a substrate 303 with a specified allowable crack length to determine whether the substrate 303 is acceptable for continued processing in the system 200. In one embodiment, a crack of about 1 mm or smaller is acceptable. Other criteria that the system controller may compare include the size of a chip in the edge of the substrate 303 or the size of an inclusion or bubble in the substrate 303. In one embodiment, a chip of about 5 mm or less may be acceptable, and an inclusion or bubble of less than about 1 mm may be acceptable. In determining whether to allow continued processing or reject each particular substrate 303, the system controller may apply a weighting scheme to the defects mapped in particular regions of the substrate. For instance, defects detected in critical areas, such as edge regions of the substrate 303, may be given significantly greater weighting than defects found in less critical areas.

In one embodiment, metrology data collected in the inspection module 206 may be analyzed by the system controller 290 to detect defects within the device substrate that may lead to breakage of the device substrate 303 within the subsequent module (i.e., processing module 212). Substrate breakage within the processing module 212 may lead to significant downtime of at least portions of the module for clean up and/or repair. Therefore, the detection and removal of problematic device substrates 303 may lead to significant throughput and cost improvements within the production line 200.

In one embodiment, the system controller 290 collects and analyzes the metrology data received from the inspection module 206 for use in determining the root cause of recurring defects in the substrate 303 so that it can correct or tune the preceding processes to eliminate the recurring defects. In one embodiment, the system controller 290 locally maps the defects detected in each substrate 303 for use in a manual or automated metrology data analysis performed by the user or system controller 290. In one embodiment, the optical characteristics of each device substrate 303 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next, the device substrate 303 is transported to the processing module 212 in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form one or more p-i-n junctions. In one embodiment, the one or more p-i-n junctions comprise amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303.

In one embodiment, the device substrate 303 is transferred to an accumulator 211A prior to being transferred to one or more of the cluster tools 212A-212D. In one embodiment, in cases where the solar cell device is formed to include multiple junctions, such as the tandem junction solar cell 300 illustrated in FIG. 3B, the cluster tool 212A in the processing module 212 is adapted to form the first p-i-n junction 320 and cluster tools 212B-212D are configured to form the second p-i-n junction 330. In such an embodiment, the device substrate 303 may optionally be transferred into an inspection module 215 for a corresponding film characterization step 115 following processing in the first cluster tool 212A. In one embodiment, the optional inspection module 215 is configured within the overall processing module 212.

In the optional deposition film characterization step 115, the device substrate 303 is inspected via the inspection module 215, and metrology data is collected and sent to the system controller 290. In one embodiment, the device substrate 303 is spectrographically inspected to determine certain characteristics of the film deposited onto the device substrate 303, such as the variation in film thickness across the surface of the device substrate 303 and the band gap of the films deposited onto the device substrate 303.

In one embodiment, the device substrate 303 is passed through the inspection module 215 via the automation device 281. As the device substrate 303 passes through the inspection module 215, the device substrate 303 is spectrographically inspected, and data is captured and sent to the system controller 290, where the data is analyzed and stored.

In one embodiment, the inspection module 215 comprises an inspection region located below or above the device substrate 303 as it is transported by an automation device 281. In one embodiment, the inspection module 215 is configured to determine the exact positioning and velocity of the device substrate 303 as it passes therethrough. Thus, all data acquired from the inspection of the device substrate 303 by the inspection module 215 as a function of time may be placed within a positional reference frame relative to points found within regions of the device substrate 303. With this information, parameters such as film thickness uniformity across the surface of the device substrate 303 may be determined and sent to the system controller 290 for collection and analysis.

In one embodiment, the data received by the system controller 290 from the inspection module 215 are analyzed by the system controller 290 to determine whether the device substrate 303 meets specified quality criteria. If the specified quality criteria are met, the device substrate 303 continues on its path in the system 200 to the next station in the processing sequence. However, if the specified criteria are not met, actions may be taken to either repair the defect or reject the defective device substrate 303. In one embodiment, data collected by the inspection module 214 is captured and analyzed in a portion of the system controller 290 disposed locally within the inspection module 215. In this embodiment, the decision to reject a particular device substrate 303 may be made locally within the inspection module 215.

In one embodiment, the system controller 290 may analyze the information received from the inspection module 215 to characterize the device substrate regarding certain film parameters. In one embodiment, the thickness and variation in thickness across the surface of the device substrates 303 may be measured and analyzed to monitor and tune the process parameters in the film deposition step 112. In one embodiment, the band gap of the deposited film layers on the device substrates 303 may be measured and analyzed to monitor and tune the process parameters in the film deposition step 112 as well.

In one embodiment, the system controller 290 collects and analyzes the metrology data received from the inspection module 215 for use in determining the root cause of recurring defects in the device substrate 303 and correcting or tuning the preceding processes to eliminate the recurring defects. For instance, if the system controller 290 determines deficiencies in the film thickness are recurring in a specific film layer, the system controller 290 may signal that the process recipe for a specific process in step 112 may need to be refined. As a result the process recipe may be automatically or manually refined to ensure that the completed solar cell devices meet desired performance criteria.

In another embodiment, the system controller 290 uses the metrology data to identify malfunctioning downstream modules or chambers. The system controller 290 may then take corrective action, such as taking the malfunctioning module or chamber offline and reconfiguring the manufacturing process flow around the malfunctioning process module or chamber within the processing module. For instance, if the system controller 290 determines deficiencies in a specific film layer consistently coming from a specific chamber, the system controller 290 may signal that chamber be taken offline and the process flow reconfigured to avoid that chamber until the chamber can be repaired.

In one embodiment of the process sequence 100, a cool down step, or step 113, is performed after step 112 has been performed. The cool down step is generally used to stabilize the temperature of the device substrate 303 to assure that the processing conditions seen by each device substrate 303 in the subsequent processing steps are repeatable. Generally, the temperature of the device substrate 303 exiting the processing module 212 could vary by many degrees Celsius and exceed a temperature of 50° C., which can cause variability in the subsequent processing steps and solar cell performance.

In one embodiment, the cool down step 113 is performed in one or more of the substrate supporting positions found in one or more accumulators 211. In one configuration of the production line, as shown in FIG. 2, the processed device substrates 303 may be positioned in one of the accumulators 211B for a desired period of time to control the temperature of the device substrate 303. In one embodiment, the system controller 290 is used to control the positioning, timing, and movement of the device substrates 303 through the accumulator(s) 211 to control the temperature of the device substrates 303 before proceeding down stream through the production line.

In the next step, or deposition film inspection step 114, the device substrate 303 is inspected via an inspection module 214, and metrology data is collected and sent to the system controller 290. In one embodiment, the device substrate 303 is optically inspected for defects in the film layers deposited in step 112, such as pinholes, that may create a short between the first TCO layer 310 and the back contact layer 350 of a fully formed solar cell device, such as the solar cell 300.

In one embodiment, the device substrate 303 is passed through the inspection module 214 via the automation device 281. As the device substrate 303 passes through the inspection module 214, the device substrate 303 is optically inspected, and images of the substrate 303 are captured and sent to the system controller 290, where the images are analyzed and metrology data is collected.

In one embodiment, the images captured by the inspection module 214 are collected by the system controller 290 and analyzed to determine whether the device substrate 303 meets specified quality criteria. If the specified quality criteria are met, the device substrate 303 continues on its path in the system 200. However, if the specified criteria are not met, actions may be taken to either repair the defect or reject the defective device substrate 303. In one embodiment, defects detected in the device substrate 303 are captured and analyzed in a portion of the system controller 290 disposed locally within the inspection module 214. In this embodiment, the decision to reject a particular device substrate 303 may be made locally within the inspection module 214.

In one embodiment, the system controller 290 may compare information received from the inspection module 214 with programmed data to determine whether a detected film defect is a pinhole extending through all of the film layers deposited in step 112 or whether the detected film defect is a partial pinhole extending through only one or two of the deposited film layers. If the system controller 290 determines that the pinhole extends through all of the layers and is of a size and/or quantity exceeding specified criteria, corrective action may be taken, such as removing the device substrate 303 for manual inspection or scrapping the device substrate 303. If the system controller 290 determines that the pinhole is a partial pinhole or that any pinholes detected are not of a size or quantity exceeding specified criteria, the device substrate 303 is transported out of the inspection module 214 for further processing in the system 200.

In one embodiment, the system controller 290 collects and analyzes the metrology data received from the inspection module 214 for use in determining the root cause of recurring defects in the device substrate 303 and correcting or tuning the preceding processes to eliminate the recurring defects. For instance, if the system controller 290 determines partial pinholes are recurring in a specific film layer, the system controller 290 may signal that a particular chamber in the processing module 212 may be contaminated, and the contaminated chamber may be taken offline to correct the problem without shutting down the entire production line. In such a scenario, the system controller 290 may take further action to reconfigure the manufacturing process flow to avoid the contaminated chamber. In another instance, the system controller may indicate that clean room filters or blowers may be contaminated and need cleaning or replacement. In one embodiment, the system controller 290 maps the defects detected in each device substrate 303, either locally or centrally, for use in metrology data analysis.

One embodiment of an optical inspection module, such as the inspection module 214, is subsequently described in more detail in the section entitled, “Optical Inspection Module.”

In the next step, or deposition film characterization step 115, the device substrate 303 is inspected via an additional inspection module 215, and metrology data is collected and sent to the system controller 290. In one embodiment, the device substrate 303 is spectrographically inspected to determine certain characteristics of the film deposited onto the device substrate 303, such as the variation in film thickness across the surface of the device substrate 303 and the band gap of the films deposited onto the device substrate 303.

In one embodiment, the device substrate 303 is passed through the inspection module 215 via the automation device 281. As the device substrate 303 passes through the inspection module 215, the device substrate 303 is spectrographically inspected, and images of the substrate 303 are captured and sent to the system controller 290, where the images are analyzed and metrology data is collected and stored.

In one embodiment of the inspection module 215, which is configured similarly to the optical inspection module 400 illustrated FIG. 4, light travels from the illumination source 415 through the substrate to a single spectral imaging sensor, such as a spectrographic sensor found in one of the optical inspection devices 420. In this configuration, light comes up through a substrate that is disposed between the illumination source 415 and the optical inspection device 420, and is diffused along all different directions, while by use of mirrors and/or lenses disposed within the inspection module 215 the light leaving the substrate can be directed to a single optical inspection device 420. Light diffraction, interference and/or reflection is a function of wavelength of light and thus the film disposed on the substrate affects the light that shines through the substrate. Thus, instead of one wavelength of light, many wavelengths are delivered though the substrate, i.e. broadband light source may be used in the illumination source 415 to improve resolution and quality of data collected. As the light passes through the substrate, it reflects from the front surface of the substrate, passes through a layer (i.e., transmission) and is refracted. Light then hits the next interface and reflects, and it is transmitted through the next layer and refracts. This process repeats as the light travels through the substrate and the layers formed thereon. The multitude of light beams that then exit the substrate and are collected by the optical inspection device 420 can be analyzed by the system controller 290, and the wavelength and other received data (e.g., light intensity) can be analyzed and described by a power series which is convergent. Thus the transmission coefficient may be calculated using Fresnel equations. Fresnel equations indicate that the percentage transmission is a function of many optical variables, such as thicknesses of various films, surface roughness, angle of light used, index of different films and wavelength. Fresnel algorithms also take into account the angle at which the light enters the substrate and make the calculations to determine the film properties based on the optical properties of the processed substrate. A regression routing analysis may be used to solve for the variables when the percentage transmission is known, such as using a Levenberg-Marquardt algorithm or a simplex algorithm. Once the film index is calculated based on the percentage transmission, the crystal fraction may be calculated based on another function that correlates the different film index to crystal function

In one embodiment, the inspection module 215 is an inspection strip located below or above the device substrate 303 as it is transported by an automation device 281. In one embodiment, the inspection module 215 is configured to determine the exact positioning and velocity of the device substrate 303 as it passes therethrough. Thus, all data acquired from the inspection module 215 as a time series may be placed within a reference frame of the device substrate 303. With this information, parameters such as uniformity of film thickness across the surface of the device substrate 303 may be determined and sent to the system controller 290 for collection and analysis.

In one embodiment of the inspection module 215, the optical inspection device 420 comprises a lens, a diffraction grating, and a focal plane array which contains many photosensors that are arranged in an array, such as a rectangular grid matrix. In operation, different wavelengths of light come out in different positions of the substrate as light passes through the substrate and form different columns in the focal plane array that are configured to receive discrete wavelengths of light, or wavelength bands, for example, at wavelengths between 600 nm and 1600 nm. As the data is collected as the panel moves over the light source, the received time related information by the optical inspection device 420 also includes position information along the panel. A data cube is thereby formed which corresponds to the wavelength of light at location X on the panel as it moves at time t, which is then mapped to create location Y, as the substrate moves in the direction of Y. The focal plane array yields a snapshot of data at an instant in time. Certain wavelengths interact with certain films, so if you use one wavelength over time over various X spots, that may indicate how the thickness varies at the spot. The system controller then compares the data collected to the theoretical properties for each substrate based on the process parameters used to process that particular substrate.

One advantage of the inspection module 215 that utilizes a single optical inspection device 420 that is positioned to receive all of the light emitted from a broad band source versus a more conventional fixed array of sensors is that the data collected by the system controller may miss an anomaly because only discrete parts of the substrate are illuminated and inspected by each sensor in the conventional sensor array. Thus, in the missing data found between the discrete parts of the substrate are blind spots. But with the embodiments of the invention, significantly more information is available because the entire substrate is illuminated. Additionally, the whole substrate may be inspected or the inspection pattern may be changed to inspect particular portions of the substrate. Embodiments of the invention also provide 100% sampling rate of all substrates, and each substrate is measured immediately after deposition. Moreover, the system controller 290 may be used to define the desired points of inspection along the substrate. The optical transmission technique is sensitive to thickness and band-edge, while insensitive to substrate alignment or vibration. Additionally, the entire substrate may be measured at 10 mm spatial resolution. Broad light wavelength range enables better metrology due to increased resolution, thus improving data collection.

In one embodiment, the data received by the system controller 290 from the inspection module 215 are analyzed by the system controller 290 to determine whether the device substrate 303 meets specified quality criteria. If the specified quality criteria are met, the device substrate 303 continues on its path in the system 200. However, if the specified criteria are not met, actions may be taken to either repair the defect or reject the defective device substrate 303. In one embodiment, data collected by the inspection module 214 is captured and analyzed in a portion of the system controller 290 disposed locally within the inspection module 215. In this embodiment, the decision to reject a particular device substrate 303 may be made locally within the inspection module 215.

In one embodiment, the system controller 290 may analyze the information received from the inspection module 215 to characterize the device substrate regarding certain film parameters. In one embodiment, the thickness and variation in thickness across the surface of the device substrates 303 may be measured and analyzed to monitor and tune the process parameters in the film deposition step 112. In one embodiment, the band gap of the deposited film layers on the device substrates 303 may be measured and analyzed to monitor and tune the process parameters in the film deposition step 112 as well. In one embodiment, metrology data collected in the two inspection modules 215 may be collected and compared in order to characterize the film layers deposited on the device substrate 303 during the deposition step 112, particularly with respect to multi-junction cells (e.g., FIG. 3B).

In one embodiment, the system controller 290 collects and analyzes the metrology data received from each inspection module 215 for use in determining the root cause of recurring defects in the device substrate 303 and correcting or tuning the preceding processes to eliminate the recurring defects. For instance, if the system controller 290 determines deficiencies in the film thickness are recurring in a specific film layer, the system controller 290 may signal that the process recipe for a specific process in step 112 may need to be refined. As a result the process recipe may be automatically or manually refined to ensure that the completed solar cell devices meet desired performance criteria.

In another embodiment, the system controller 290 uses the metrology data to identify malfunctioning downstream modules or chambers. The system controller 290 may then take corrective action, such as taking the malfunctioning module or chamber offline and reconfiguring the manufacturing process flow around the malfunctioning process module or chamber within the processing module. For instance, if the system controller 290 determines deficiencies in a specific film layer consistently coming from a specific chamber, the system controller 290 may signal that chamber be taken offline and the process flow reconfigured to avoid that chamber until the chamber can be repaired.

Next, the device substrate 303 is transported to the scribe module 216 in which step 116, or the interconnect formation step, is performed on the device substrate 303 to electrically isolate various regions of the device substrate 303 surface from each other. In step 116, material is removed from the device substrate 303 surface by use of a material removal step, such as a laser ablation process. In one embodiment, an Nd:vanadate (Nd:YVO₄) laser source is used ablate material from the substrate surface to form lines that electrically isolate one solar cell from the next. In one embodiment, a 5.7 m² substrate laser scribe module available from Applied Materials, Inc. is used to perform the accurate scribing process. In one embodiment, the laser scribe process performed during step 108 uses a 532 nm wavelength pulsed laser to pattern the material disposed on the device substrate 303 to isolate the individual cells that make up the solar cell 300. As shown in FIG. 3E, in one embodiment, the trench 381B is formed in the first p-i-n junction 320 layers by used of a laser scribing process. In another embodiment, a water jet cutting tool or diamond scribe is used to isolate the various regions on the surface of the solar cell. In one aspect, it is desirable to assure that the temperature of the device substrates 303 entering the scribe module 216 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25+/−0.5° C.

In one embodiment, the solar cell production line 200 has at least one accumulator 211 positioned after the scribe module(s) 216. During production accumulators 211C may be used to provide a ready supply of substrates to the processing module 218, and/or provide a collection area where substrates coming from the processing module 212 can be stored if the processing module 218 goes down or can not keep up with the throughput of the scribe module(s) 216. In one embodiment it is generally desirable to monitor and/or actively control the temperature of the substrates exiting the accumulators 211C to assure that the results of the back contact formation step 120 are repeatable. In one aspect, it is desirable to assure that the temperature of the substrates exiting the accumulators 211C or arriving at the processing module 218 are at a temperature in a range between about 20° C. and about 26° C. In one embodiment, it is desirable to control the substrate temperature to about 25+/−0.5° C. In one embodiment, it is desirable to position one or more accumulators 211C that are able to retain at least about 80 substrates.

Next, the device substrate 303 may be transported to an inspection module 217 in which a laser inspection step 117 may be performed and metrology data may be collected and sent to the system controller 290. In one embodiment of the laser inspection step 117, as the substrate 303 passes through the inspection module 217, the substrate 303 is optically inspected, and images of the substrate 303 are captured and sent to the system controller 290, where the images are analyzed and metrology data is collected and stored in memory.

In one embodiment, the inspection module 217 generates images of laser scribe regions within the device substrate 303. After the system controller 290 receives the images, the system controller 290 may perform a digitized scan of the images to determine various visual characteristics of the laser scribe regions and extract various morphological parameters, the system controller 290 may then tune laser scribe parameters in the scribe module 216 to correct process drift, to identify a misprocessed device substrate 303, or to identify an error in the scribe module 216.

Based on the visual analysis of the laser scribe image, morphological parameters indicative of the laser scribe process quality and stability may be extracted. In one embodiment, the controller 290 is used to analyze a digital image received by the inspection module 217 of a scribe formed on the substrate's surface during a scribing process. Some of the morphological parameters may be fuzziness, minor axis, major axis, eccentricity, effectiveness, overlap area, and color uniformity of the laser scribe.

In one embodiment, the images captured by the inspection module 217 are analyzed by the system controller 290 to determine whether the laser scribe regions of the substrate 303 meets specified quality criteria. If the specified quality criteria are met, the substrate 303 continues on its path in the system 200. However, if the specified criteria are not met, actions may be taken to either repair the defect or reject the defective substrate 303. In one embodiment, the device substrate 303 may be returned to the scribe module 216 for further processing. In one embodiment, defects detected in the substrate 303 are mapped and analyzed in a portion of the system controller 290 disposed locally within the inspection module 217. In this embodiment, the decision to reject a particular substrate 303 may be made locally within the inspection module 217. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next, the device substrate 303 is transported to the processing module 218 in which one or more substrate back contact formation steps, or step 118, are performed on the device substrate 303. In step 118, the one or more substrate back contact formation steps may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from a group consisting of zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 305. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303.

In one embodiment, the solar cell production line 200 has at least one accumulator 211 positioned after the processing module 218. During production, the accumulators 211D may be used to provide a ready supply of substrates to the scribe modules 220, and/or provide a collection area where substrates coming from the processing module 218 can be stored if the scribe modules 220 go down or can not keep up with the throughput of the processing module 218. In one embodiment it is generally desirable to monitor and/or actively control the temperature of the substrates exiting the accumulators 211D to assure that the results of the back contact formation step 120 are repeatable. In one aspect, it is desirable to assure that the temperature of the substrates exiting the accumulators 211D or arriving at the scribe module 220 is at a temperature in a range between about 20° C. and about 26° C. In one embodiment, it is desirable to control the substrate temperature to about 25+/−0.5° C. In one embodiment, it is desirable to position one or more accumulators 211C that are able to retain at least about 80 substrates.

Next, the device substrate 303 is transported to an inspection module 219 in which an inspection step 119 is performed on the device substrate 303. In one embodiment, the sheet resistance of the back contact layer 350 is measured by the inspection module 219 and metrology data is collected, analyzed, and stored by the system controller 290. In one embodiment, optical reflective properties of the back contact layer 350 are measured by the inspection module 219 and metrology data is collected, analyzed, and stored by the system controller 290.

FIG. 3G is a schematic, cross-sectional view of a portion of a particular device substrate 303 being inspected in the inspection module 219. In one embodiment, the inspection module 219 measures the quality and material properties of the back contact layer 350 of the device substrate 303 by use of probes 391, a light source 398, a voltage source 392, a measurement device 393, sensors 384, and the system controller 290. In one embodiment, the light source 398 within the inspection module 219 projects a low level of light toward the device substrate 303 while the sensors 384 measure the reflectivity of the back contact layer 350. In one embodiment, the light source 398 comprises a plurality of light emitting diodes (LED's). In such an embodiment, light from the individual LED's may be projected onto a localized region of the device substrate 303, such as the edge regions 385 and reflectivity of the back contact layer 350 may be obtained. In one embodiment, the light source 398 includes one or more lamps or LED's that project a spectrum of light simulating the solar spectrum. In one embodiment, the light source 398 is configured to vary the light intensity for increasing the ability to identify certain properties or defects within the device substrate 303. For instance, the light source 398 may emit only wavelengths of light in the red spectrum, only wavelengths of light in the blue spectrum, wavelengths of light in the red spectrum followed by wavelengths of light in the blue spectrum, or some other combination of spectral emission.

In one embodiment, the device substrate 303 passes through the inspection module 219 via the automation device 281. As the device substrate 303 passes through the inspection module, a voltage is applied across the back contact layer 350 via the voltage source 392, and the back contact layer 350 is probed via probes 391 and the resistance is measured via the measurement device 393 to determine the sheet resistance of the back contact layer 350. The measured information may be transmitted to the system controller 290, where the data is collected, analyzed, and stored.

In one embodiment, the system controller 290 collects and analyzes the metrology data received from the inspection module 219 for use in determining the root cause of recurring defects in the device substrate 303 and correcting or tuning the preceding processes to eliminate the recurring defects. For instance, if the system controller 290 determines deficiencies in the reflectivity of the back contact layer 350 are recurring, the system controller 290 may signal that the process recipe for a specific process in step 118 may need to be refined. As a result the process recipe may be automatically or manually refined to ensure that the completed solar cell devices meet desired performance criteria. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

In one embodiment, the device substrate 303 may be optionally transferred into another inspection module 206, where a corresponding inspection step 106 may be performed on the device substrate 303 to detect any damage caused by handling devices within the scribe module 216 or the processing module 218. In one embodiment, the substrate 303 is passed through the inspection module 206 via the automation device 281. In one embodiment of the inspection step 106, as the substrate 303 passes through the inspection module 206, the substrate 303 is optically inspected, and images of the substrate 303 are captured and sent to the system controller 290, where the images are analyzed and metrology data is collected and stored in memory.

In one embodiment, the images captured by the inspection module 206 are analyzed by the system controller 290 to determine whether the substrate 303 meets specified quality criteria. If the specified quality criteria are met, the substrate 303 continues on its path in the system 200. However, if the specified criteria are not met, actions may be taken to either repair the defect or reject the defective substrate 303. In one embodiment, defects detected in the substrate 303 are mapped and analyzed in a portion of the system controller 290 disposed locally within the inspection module 206. In this embodiment, the decision to reject a particular substrate 303 may be made locally within the inspection module 206.

In one embodiment, the system controller 290 may compare information regarding the size of a crack on an edge of a substrate 303 with a specified allowable crack length to determine whether the substrate 303 is acceptable for continued processing in the system 200. In one embodiment, a crack of about 1 mm or smaller is acceptable. Other criteria that the system controller may compare include the size of a chip in the edge of the substrate 303 or the size of an inclusion or bubble in the substrate 303. In one embodiment, a chip of about 5 mm or less may be acceptable, and an inclusion or bubble of less than about 1 mm may be acceptable. In determining whether to allow continued processing or reject each particular substrate 303, the system controller may apply a weighting scheme to the defects mapped in particular regions of the substrate. For instance, defects detected in critical areas, such as edge regions of the substrate 303, may be given significantly greater weighting than defects found in less critical areas.

In one embodiment, the system controller 290 collects and analyzes the metrology data received from the inspection module 206 for use in determining the root cause of recurring defects in the substrate 303 so that it can correct or tune the preceding processes to eliminate the recurring defects. In one embodiment, the system controller 290 locally maps the defects detected in each substrate 303 for use in a manual or automated metrology data analysis performed by the user or system controller 290. In one embodiment, the optical characteristics of each device substrate 303 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next, the device substrate 303 is transported to the scribe module 220 in which step 120, or a back contact isolation step, is performed on the device substrate 303 to electrically isolate the plurality of solar cells contained on the substrate surface from each other. In step 120, material is removed from the substrate surface by use of a material removal step, such as a laser ablation process. In one embodiment, a Nd:vanadate (Nd:YVO₄) laser source is used ablate material from the device substrate 303 surface to form lines that electrically isolate one solar cell from the next. In one embodiment, a 5.7 m² substrate laser scribe module, available from Applied Materials, Inc., is used to accurately scribe the desired regions of the device substrate 303. In one embodiment, the laser scribe process performed during step 120 uses a 532 nm wavelength pulsed laser to pattern the material disposed on the device substrate 303 to isolate the individual cells that make up the solar cell 300. As shown in FIG. 3E, in one embodiment, the trench 381C is formed in the first p-i-n junction 320 and back contact layer 350 by use of a laser scribing process. In one aspect, it is desirable to assure that the temperature of the device substrates 303 entering the scribe module 220 are at a temperature in a range between about 20° C. and about 26° C. by use of an active temperature control hardware assembly that may contain a resistive heater and/or chiller components (e.g., heat exchanger, thermoelectric device). In one embodiment, it is desirable to control the substrate temperature to about 25+/−0.5° C.

Next, the device substrate 303 may be transported to an inspection module 221 in which a laser inspection step 121 may be performed and metrology data may be collected and sent to the system controller 290. In one embodiment of the laser inspection step 121, as the substrate 303 passes through the inspection module 221, the substrate 303 is optically inspected, and images of the substrate 303 are captured and sent to the system controller 290, where the images are analyzed and metrology data is collected and stored in memory.

In one embodiment, the inspection module 221 generates images of laser scribe regions within the device substrate 303. After the system controller 290 receives the images, the system controller 290 may perform a digitized scan of the images to determine various visual characteristics of the laser scribe regions and extract various morphological parameters, the system controller 290 may then tune laser scribe parameters in the scribe module 220 to correct process drift, to identify a misprocessed device substrate 303, or to identify an error in the scribe module 220.

Based on the visual analysis of the laser scribe image, morphological parameters indicative of the laser scribe process quality and stability may be extracted. In one embodiment, the controller 290 is used to analyze a digital image received by the inspection module 221 of a scribe formed on the substrate's surface during a scribing process. Some of the morphological parameters may be fuzziness, minor axis, major axis, eccentricity, effectiveness, overlap area, and color uniformity of the laser scribe.

In one embodiment, the images captured by the inspection module 221 are analyzed by the system controller 290 to determine whether the laser scribe regions of the substrate 303 meets specified quality criteria. If the specified quality criteria are met, the substrate 303 continues on its path in the production line 200. However, if the specified criteria are not met, actions may be taken to either repair the defect or reject the defective substrate 303. In one embodiment, the device substrate 303 may be returned to the scribe module 220 for further processing. In one embodiment, defects detected in the substrate 303 are mapped and analyzed in a portion of the system controller 290 disposed locally within the inspection module 221. In this embodiment, the decision to reject a particular substrate 303 may be made locally within the inspection module 221. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next, the device substrate 303 is transported to the quality assurance module 222 in which step 122, or quality assurance and/or shunt removal steps, are performed on the device substrate 303 to assure that it meets a desired quality standard and, in some cases, corrects defects in the formed solar cell device. The quality assurance module measures a number of electrical characteristics of the device substrate 303, and the collected metrology data is then sent to and stored within the system controller 290. FIG. 3H is a schematic, cross-sectional view of a portion of a particular device substrate 303 being inspected in the quality assurance module 222.

In one embodiment, the quality assurance module 222 probes each individual cell 382 of the device substrate 303 to determine whether a conductive path, or short, exists between adjacent cells 382. In one embodiment, the device substrate 303 is passed through the quality assurance module 222 via the automation device 281. As the device substrate 303 passes through the quality assurance module 222, each pair of adjacent cells 382 are probed for electrical continuity via probes 391 as shown in FIG. 3G. In one embodiment, a voltage is applied between adjacent cells 382 on the device substrate 303, and a resistance between probes 391 that are in contact with the adjacent cells 382 is measured. If the measurement exceeds a specified criterion, such as about 1 kΩ, an instruction may be sent that no continuity exists between the probed cells 382. If the measurement is less than a specified criterion, such as about 150Ω, an instruction may be sent that continuity, or a short, exists between the probed cells 382. The information regarding continuity of the cells 382 may be transmitted to the system controller 290, where the data is collected, analyzed, and stored.

In one embodiment, if a short or other similar defect is found between two adjacent cells 382, the quality assurance module 222 initiates a reverse bias voltage between the adjacent cells 382 to correct the defect in the device substrate 303. During this correction process the quality assurance module 222 delivers a voltage high enough to cause the defects between the adjacent cells 382 to change phase, decompose, or become altered in some way to eliminate or reduce the magnitude of the electrical short. In one embodiment, the magnitude of the voltage to be delivered in the aforementioned shunt busting operation may be determined by measuring the diode junction capacitance of each cell 382 as subsequently described. In one embodiment, a particular device substrate 303 may be sent back upstream in the processing sequence 100 to allow one or more fabrication steps to be re-performed on the device substrate 303 (e.g., back contact isolation step (step 120)) to correct the detected quality issues with the processed device substrate 303.

In one embodiment, the quality assurance module 222 measures the quality and material properties of the device substrate 303 by use of probes 391, the light source 398, the voltage source 392, the measurement device 393, and the system controller 290. In one embodiment, the light source 398 within the quality assurance module 222 projects a low level of light at the p-i-n junction(s) of the device substrate 303 while the probes 391 measure the output of each cell 382 to determine the electrical characteristics of the device substrate 303. In one embodiment, the diode junction capacitance of each cell 382 is measured to determine the existence and magnitude of any shunts between adjacent cells 382, which allows real time adjustment the magnitude of voltage used for any shunt busting operations as previously described.

In one embodiment, the light source 398 comprises a plurality of light emitting diodes (LED's). In such an embodiment, light from the individual LED's may be projected onto a localized region of the device substrate 303, and the electrical characteristics of the localized region may be obtained, and electrical characteristics for the entire device substrate 303 may be mapped. In one embodiment, the light source 398 includes one or more lamps or LED's that project a spectrum of light simulating the solar spectrum. In one embodiment, the light source 398 is configured to vary the light intensity for increasing the ability to identify certain properties or defects within the device substrate 303. For instance, the light source 398 may emit only wavelengths of light in the red spectrum, only wavelengths of light in the blue spectrum, wavelengths of light in the red spectrum followed by wavelengths of light in the blue spectrum, or some other combination of spectral emission.

In one embodiment, the quality assurance module 222 is configured to measure and record a number of properties of a particular device substrate 303, such as photocurrent, series resistance, sheet resistance, open current voltage, dark current, and spectral response. In one embodiment, the quality assurance module 222 is configured to send current and voltage information to the system controller 290 for mapping the quality of each individual device substrate 303 by region. In one embodiment, the quality assurance module 222 includes one or more screens (not shown) for blocking ambient light during dark current measurement, which provides information regarding particular defects at the solar cell junction, for instance.

FIG. 3I is a schematic, partial, plan view of a depiction of a device substrate 303 being inspected by the quality assurance module 222 and having defects mapped thereon. In one embodiment, the quality assurance module 222 further includes a variable resistor 375 connected in series across the two outermost cells 382, as shown in FIG. 3I. Referring to both FIG. 3H and FIG. 3I, the variable resistor 375 may be set to a desired resistance, and the light source 398 may emit light simulating the solar spectrum at the device substrate 303, while the measurement device 393 captures voltage and/or current readings across adjacent cells 382. For instance, the variable resistor 375 may be set to 0 to achieve a closed circuit condition. In another example, the variable resistor 375 may be set to infinite resistance to achieve and open circuit condition. In yet another example, the variable resistor 375 may be set at a desired resistance to achieve a maximum power condition. In any of the three aforementioned examples, the voltage may be measured at each cell 382 and sent to the system controller 290 for storage and analysis.

In one embodiment, the voltage readings at each cell 382 under one or more of the closed circuit condition or maximum power condition may be mapped either locally or centrally within the system controller 290 for each device substrate 303. The map of the voltages of each cell 382 of the device substrate 303 may then be analyzed and used to identify non-uniformities within the device substrate 303. For instance, under closed circuit conditions, cells 382 with negative voltage readings indicate areas with thinner first p-i-n junctions 320 and/or second p-i-n junctions 330 than cells 382 with positive voltage readings. In another example, under maximum power conditions, cells 382 with lower voltage readings indicate areas with thinner first p-i-n junctions 320 and/or second p-i-n junctions 330 than cells 382 with high voltage readings. Thus, the information obtained from the voltage readings under particular conditions may be used to map the relative thickness of the first p-i-n junctions 320 and/or second p-i-n junctions 330 across the surface of the device substrate 303.

In one embodiment, each cell 382 of a particular device substrate 303 is divided into a plurality of portions via scribe lines 381 in cross-scribe regions, such as the cross-scribe region 383, in order to reduce the current flowing in each cell of the fully formed solar cell device. In such an embodiment, the quality assurance module 222 may be configured to probe across the cells 382 to detect cross-cell defects between the cells 382, as depicted in region 383 of FIG. 3I. The relative thickness of the first p-i-n junctions 320 and/or second p-i-n junctions 330 across the surface of the device substrate 303 may be mapped by probing each cell 382 across the cross-scribe region 383 under desired condition, such as closed circuit, open circuit, or maximum power conditions as well.

Additionally, the quality assurance module 222 may be configured to identify and record a variety of other defects within a particular device substrate 303, including cell to cell defects and edge isolation defects. For example, one type of cell to cell defect may include a defect in scribe lines 381 between the individual cells 382 that allows undesired passage of current as schematically depicted in region 395 of FIG. 3I. In another example, one type of edge isolation defect may include a defect in scribe lines 381 in an edge isolation region 394 that allows undesired passage of current between adjacent cells 382 in the edge isolation region 394 as schematically depicted in FIG. 3I. In one embodiment, information regarding the measured properties and identified defects may be sent to the system controller 290 and stored for further analysis. In one embodiment, property and/or defect mapping of each device substrate 303 or lot of device substrates 303 is produced by the system controller 290.

In one embodiment, the information captured by the quality assurance module 222 is analyzed by the system controller 290 to determine whether each device substrate 303 meets specified quality criteria. If the specified quality criteria are met, the device substrate 303 continues on its path in the system 200. However, if the specified criteria are not met, actions may be taken to either repair the defect or reject the effective device substrate 303. In one embodiment, defects detected in the device substrate 303 are captured and analyzed in a portion of the system controller 290 disposed locally within the quality assurance module 222. In this embodiment, the decision to reject a particular device substrate 303 may be made locally within the quality assurance module 222.

In one embodiment, the system controller 290 collects and analyzes the metrology data received from the quality assurance module 222 for use in determining the root cause of recurring defects in the device substrate 303 and correcting or tuning preceding processes, such as the preceding steps 102-120. For instance, if shorts between particular cells 382 are continually recurring, the control system 290 may issue an alert that preceding processes (such as the back contact isolation step 120) need to be corrected or tuned to prevent the recurring defects in subsequent device substrates 303. In one embodiment, the preceding processes may be manually analyzed and corrected or tuned to cure the source of recurring defects. In another embodiment, the system controller 290 may be programmed to diagnose and correct or tune one or more preceding processes (steps 102-120) to cure the source of recurring defects.

In another example, the spectral response to wavelengths of light in the blue spectrum is measured via the quality assurance module 222 and analyzed by the system controller 290. The results of the analysis may then be used to tune the processes in step 112 to optimize certain parameters of the p-i-n junction 320 (FIG. 3A) formation, such as the thickness and quality of the first p-type amorphous silicon layer 322 (FIG. 3A). For instance, if the response to wavelengths of light in the blue spectrum in certain regions of the device substrates 303 is below a certain threshold, the processes in step 112 may be tuned to decrease the thickness of the p-layer in the corresponding regions. Correspondingly, if the open current voltage in certain regions of the device substrates 303 is below a certain threshold, the processes in step 112 may be tuned to increase the thickness of the p-layer in the corresponding regions.

In another example, the maps of the device substrates 303 depicting relative thickness of the first p-i-n junctions 320 and/or second p-i-n junctions 330 across the device substrate 303 may be used to tune the processes in step 112 to provide for uniform film thickness. Alternatively, the maps of the device substrates 303 depicting relative thickness of the first p-i-n junctions 320 and/or second p-i-n junctions 330 across the device substrate 303 may be used to adjust the spacing between the various scribe lines within the scribe modules 208, 216, and/or 220 to compensate for the varying thickness of the film layers. For example, the scribe modules 208, 216, and 220 may be set to scribe lines closer together in regions of the device substrate 303 having thicker first p-i-n junctions 320 and/or second p-i-n junctions 330. As a result, non-uniformity in the film thickness may be compensated for by making the cells 382 wider or narrower in order to even out the voltage produced by each cell 382 across the surface of the device substrate 303.

In one embodiment, the device substrate 303 may be optionally transferred into another inspection module 206, where a corresponding inspection step 106 may be performed on the device substrate 303 to detect any damage caused by handling devices within the scribe module 220. In one embodiment, the substrate 303 is passed through the inspection module 206 via the automation device 281. In one embodiment of the inspection step 106, as the substrate 303 passes through the inspection module 206, the substrate 303 is optically inspected, and images of the substrate 303 are captured and sent to the system controller 290, where the images are analyzed and metrology data is collected and stored in memory.

In one embodiment, the images captured by the inspection module 206 are analyzed by the system controller 290 to determine whether the substrate 303 meets specified quality criteria. If the specified quality criteria are met, the substrate 303 continues on its path in the system 200. However, if the specified criteria are not met, actions may be taken to either repair the defect or reject the defective substrate 303. In one embodiment, defects detected in the substrate 303 are mapped and analyzed in a portion of the system controller 290 disposed locally within the inspection module 206. In this embodiment, the decision to reject a particular substrate 303 may be made locally within the inspection module 206.

In one embodiment, the system controller 290 may compare information regarding the size of a crack on an edge of a substrate 303 with a specified allowable crack length to determine whether the substrate 303 is acceptable for continued processing in the system 200. In one embodiment, a crack of about 1 mm or smaller is acceptable. Other criteria that the system controller may compare include the size of a chip in the edge of the substrate 303 or the size of an inclusion or bubble in the substrate 303. In one embodiment, a chip of about 5 mm or less may be acceptable, and an inclusion or bubble of less than about 1 mm may be acceptable. In determining whether to allow continued processing or reject each particular substrate 303, the system controller may apply a weighting scheme to the defects mapped in particular regions of the substrate. For instance, defects detected in critical areas, such as edge regions of the substrate 303, may be given significantly greater weighting than defects found in less critical areas.

In one embodiment, the system controller 290 collects and analyzes the metrology data received from the inspection module 206 for use in determining the root cause of recurring defects in the substrate 303 so that it can correct or tune the preceding processes to eliminate the recurring defects. In one embodiment, the system controller 290 locally maps the defects detected in each substrate 303 for use in a manual or automated metrology data analysis performed by the user or system controller 290. In one embodiment, the optical characteristics of each device substrate 303 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next, the device substrate 303 is optionally transported to the substrate sectioning module 224 in which a substrate sectioning step 124 is used to cut the device substrate 303 into a plurality of smaller device substrates 303 to form a plurality of smaller solar cell devices. In one embodiment of step 124, the device substrate 303 is inserted into substrate sectioning module 224 that uses a CNC glass cutting tool to accurately cut and section the device substrate 303 to form solar cell devices that are a desired size. In one embodiment, the device substrate 303 is inserted into the sectioning module 224 that uses a glass scribing tool to accurately score the surface of the device substrate 303. The device substrate 303 is then broken along the scored lines to produce the desired size and number of sections needed for the completion of the solar cell devices.

In one embodiment, the solar cell production line 200 is adapted to accept (step 102) and process substrate 302 or device substrates 303 that are 5.7 m² or larger. In one embodiment, these large area substrates 302 are partially processed and then sectioned into four 1.4 m² device substrates 303 during step 124. In one embodiment, the system is designed to process large device substrates 303 (e.g., TCO coated 2200 mm×2600 mm×3 mm glass) and produce various sized solar cell devices without additional equipment or processing steps. Currently amorphous silicon (a-Si) thin film factories must have one product line for each different size solar cell device. In the present invention, the manufacturing line is able to quickly switch to manufacture different solar cell device sizes. In one aspect of the invention, the manufacturing line is able to provide a high solar cell device throughput, which is typically measured in Mega-Watts per year, by forming solar cell devices on a single large substrate and then sectioning the substrate to form solar cells of a more preferable size.

In one embodiment of the production line 200, the front end of the line (FEOL) (e.g., steps 102-122) is designed to process a large area device substrate 303 (e.g., 2200 mm×2600 mm), and the back end of the line (BEOL) is designed to further process the large area device substrate 303 or multiple smaller device substrates 303 formed by use of the sectioning process. In this configuration, the remainder of the manufacturing line accepts and further processes the various sizes. The flexibility in output with a single input is unique in the solar thin film industry and offers significant savings in capital expenditure. The material cost for the input glass is also lower since solar cell device manufacturers can purchase a larger quantity of a single glass size to produce the various size modules.

In one embodiment, steps 102-122 can be configured to use equipment that is adapted to perform process steps on large device substrates 303, such as 2200 mm×2600 mm×3 mm glass device substrates 303, and steps 124 onward can be adapted to fabricate various smaller sized solar cell devices with no additional equipment required. In another embodiment, step 124 is positioned in the process sequence 200 prior to step 122 so that the initially large device substrate 303 can be sectioned to form multiple individual solar cells that are then tested and characterized one at a time or as a group (i.e., two or more at a time). In this case, steps 102-121 are configured to use equipment that is adapted to perform process steps on large device substrates 303, such as 2200 mm×2600 mm×3 mm glass substrates, and steps 122 and 124 onward are adapted to fabricate various smaller sized modules with no additional equipment required.

In one embodiment, the device substrate 303 may be optionally transferred into another inspection module 206, where a corresponding inspection step 106 may be performed on the device substrate 303 to detect any damage caused by handling devices within the scribe module 216 or the sectioning module 224. In one embodiment, the substrate 303 is passed through the inspection module 206 via the automation device 281. In one embodiment of the inspection step 106, as the substrate 303 passes through the inspection module 206, the substrate 303 is optically inspected, and images of the substrate 303 are captured and sent to the system controller 290, where the images are analyzed and metrology data is collected and stored in memory.

In one embodiment, the images captured by the inspection module 206 are analyzed by the system controller 290 to determine whether the substrate 303 meets specified quality criteria. If the specified quality criteria are met, the substrate 303 continues on its path in the system 200. However, if the specified criteria are not met, actions may be taken to either repair the defect or reject the defective substrate 303. In one embodiment, defects detected in the substrate 303 are mapped and analyzed in a portion of the system controller 290 disposed locally within the inspection module 206. In this embodiment, the decision to reject a particular substrate 303 may be made locally within the inspection module 206.

In one embodiment, the system controller 290 may compare information regarding the size of a crack on an edge of a substrate 303 with a specified allowable crack length to determine whether the substrate 303 is acceptable for continued processing in the system 200. In one embodiment, a crack of about 1 mm or smaller is acceptable. Other criteria that the system controller may compare include the size of a chip in the edge of the substrate 303 or the size of an inclusion or bubble in the substrate 303. In one embodiment, a chip of about 5 mm or less may be acceptable, and an inclusion or bubble of less than about 1 mm may be acceptable. In determining whether to allow continued processing or reject each particular substrate 303, the system controller may apply a weighting scheme to the defects mapped in particular regions of the substrate. For instance, defects detected in critical areas, such as edge regions of the substrate 303, may be given significantly greater weighting than defects found in less critical areas.

In one embodiment, the system controller 290 collects and analyzes the metrology data received from the inspection module 206 for use in determining the root cause of recurring defects in the substrate 303 so that it can correct or tune the preceding processes to eliminate the recurring defects. In one embodiment, the system controller 290 locally maps the defects detected in each substrate 303 for use in a manual or automated metrology data analysis performed by the user or system controller 290. In one embodiment, the optical characteristics of each device substrate 303 are compared with downstream metrology data in order to correlate and diagnose trends in the production line 200. In one embodiment, a user or the system controller 290 may take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Referring back to FIGS. 1 and 2, the device substrate 303 is next transported to the seamer/edge deletion module 226 in which a substrate surface and edge preparation step 126 is used to prepare various surfaces of the device substrate 303 to prevent yield issues later on in the process. In one embodiment of step 126, the device substrate 303 is inserted into seamer/edge deletion module 226 to prepare the edges of the device substrate 303 to shape and prepare the edges of the device substrate 303. Damage to the device substrate 303 edge can affect the device yield and the cost to produce a usable solar cell device. In another embodiment, the seamer/edge deletion module 226 is used to remove deposited material from the edge of the device substrate 303 (e.g., 10 mm) to provide a region that can be used to form a reliable seal between the device substrate 303 and the backside glass (i.e., steps 134-136 discussed below). Material removal from the edge of the device substrate 303 may also be useful to prevent electrical shorts in the final formed solar cell.

In one embodiment, a diamond impregnated belt is used to grind the deposited material from the edge regions of the device substrate 303. In another embodiment, a grinding wheel is used to grind the deposited material from the edge regions of the device substrate 303. In another embodiment, dual grinding wheels are used to remove the deposited material from the edge of the device substrate 303. In yet another embodiment, grit blasting or laser ablation techniques are used to remove the deposited material from the edge of the device substrate 303. In one aspect, the seamer/edge deletion module 226 is used to round or bevel the edges of the device substrate 303 by use of shaped grinding wheels, angled and aligned belt sanders, and/or abrasive wheels.

Next the device substrate 303 is transported to the pre-screen module 227 in which optional pre-screen steps 127 are performed on the device substrate 303 to assure that the devices formed on the substrate surface meet a desired quality standard. In step 127, a light emitting source and probing device are used to measure the output of the formed solar cell device by use of one or more substrate contacting probes. If the module 227 detects a defect in the formed device it can take corrective actions or the solar cell can be scrapped.

Next the device substrate 303 is transported to the cleaning module 228 in which step 128, or a pre-lamination substrate cleaning step, is performed on the device substrate 303 to remove any contaminants found on the surface of the substrates 303 after performing steps 122-127. Typically, the cleaning module 228 uses wet chemical scrubbing and rinsing steps to remove any undesirable contaminants found on the substrate surface after performing the cell isolation step. In one embodiment, a cleaning process similar to the processes described in step 105 is performed on the substrate 303 to remove any contaminants on the surface(s) of the substrate 303.

In the next step, or substrate inspection step 129, the device substrate 303 is inspected via an inspection module 229, and metrology data is collected and sent to the system controller 290. In one embodiment, the device substrate 303 is optically inspected for defects, such as chips, cracks, or scratches that may inhibit performance of a fully formed solar cell device, such as the solar cell 300.

In one embodiment, the device substrate 303 passes through the inspection module 229 by use of an automation device 281. As the device substrate 303 passes through the inspection module 229, the device substrate 303 is optically inspected, and images of the device substrate 303 are captured and sent to the system controller 290, where the images are analyzed and metrology data is collected and stored.

In one embodiment, the images captured by the inspection module 229 are analyzed by the system controller 290 to determine whether the device substrate 303 meets specified quality criteria. If the specified quality criteria are met, the device substrate 303 continues on its path in the system 200. However, if the specified criteria are not met, actions may be taken to either repair the defect or reject the defective device substrate 303. In one embodiment, defects detected in the device substrate 303 are mapped and analyzed in a portion of the system controller 290 disposed locally within the inspection module 229. In this embodiment, the decision to reject a particular device substrate 303 may be made locally within the inspection module 229.

In one example, the system controller 290 may compare information regarding the size of a crack on an edge of a device substrate 303 with a specified allowable crack length to determine whether the substrate 303 should continue being processed in the system 200. In one embodiment, a crack of about 1 mm or smaller is acceptable. Other criteria that the system controller may compare include the size of a chip in the edge of the device substrate 303. In one embodiment, a chip of about 5 mm or less is acceptable. In determining whether to allow continued processing or reject each particular substrate 302, 303, the system controller may apply a weighting scheme to the defects mapped in particular regions of the substrate. For instance, defects detected in critical areas, such as edge regions of the device substrate 303, may be given significantly greater weighting than defects found in less critical areas.

In one embodiment, the system controller 290 collects and analyzes the metrology data received from the inspection module 229 for use in determining the root cause of recurring defects in the device substrate 303 so that it can correct or tune the preceding processes, such as substrate sectioning step 124 or edge preparation step 126, to eliminate the recurring defects. In one embodiment, the system controller 290 maps the defects detected in each device substrate 303, either locally or centrally, for use in metrology data analysis. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

One embodiment of an optical inspection module, such as the inspection module 229 is subsequently described in more detail in the section entitled, “Optical Inspection Module.”

In the next step, or edge inspection step 130, each device substrate 303 is inspected via an inspection module 230, and metrology data is collected and sent to the system controller 290. In one embodiment, edges of the device substrate 303 are inspected via an optical interferometry technique to detect any residues in the edge deletion area that may create shorts or paths in which the external environment can attack portions of a fully formed solar cell device, such as the solar cell 300.

In one embodiment, the device substrate 303 is passed through the inspection module 230 via an automation device 281. As the device substrate 303 passes through the inspection module 230, edge deletion regions of the device substrate 303 are interferometrically inspected, and information obtained from the inspection is sent to the system controller 290 for collection and analysis.

In one embodiment, the inspection module 230 determines the surface profile of the device substrate 303 in the edge deletion area. A portion of the system controller 290 disposed locally within the inspection module 230 may analyze the surface profile data collected to assure that edge deletion area profile is within a desired range. If the specified profile criteria are met, the device substrate 303 continues on its path in the system 200. However, if the specified profile criteria are not met, actions may be taken to either repair the defect or reject the defective device substrate 303.

In one example, the system controller 290, either locally or centrally, may compare information regarding the height of the edge deletion region of the device substrate 303 with a specified height range to determine whether the device substrate 303 is acceptable for continued processing in the system 200. In one embodiment, if the edge deletion region height is determined to be too great in a particular region, the device substrate may be sent back to the seamer/edge deletion module 226 for repair in the edge preparation step 126. In one embodiment, if the edge profile is not at least about 10 μm lower than the front surface of the device substrate 303, the device substrate 303 is rejected for reprocessing, such as the edge preparation process 126, or scrapping.

In one embodiment, the system controller 290 collects, analyzes, and stores the metrology data received from the inspection module 229 for use in determining the root cause of recurring defects in the device substrate 303 and correct or tune the preceding edge preparation processes to eliminate the recurring defects. In one embodiment, the data collected by the inspection module 229 may indicate that maintenance or part replacement is needed in an upstream module, such as the seamer/edge deletion module 226. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next the substrate 303 is transported to a bonding wire attach module 231 in which step 131, or a bonding wire attach step, is performed on the substrate 303. Step 131 is used to attach the various wires/leads required to connect the various external electrical components to the formed solar cell device. Typically, the bonding wire attach module 231 is an automated wire bonding tool that is advantageously used to reliably and quickly form the numerous interconnects that are often required to form the large solar cells formed in the production line 200. In one embodiment, the bonding wire attach module 231 is used to form the side-buss 355 (FIG. 3C) and cross-buss 356 on the formed back contact region (step 118). In this configuration the side-buss 355 may be a conductive material that can be affixed, bonded, and/or fused to the back contact layer 350 found in the back contact region to form a good electrical contact. In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick. The cross-buss 356, which is electrically connected to the side-buss 355 at the junctions, can be electrically isolated from the back contact layer(s) of the solar cell by use of an insulating material 357, such as an insulating tape. The ends of each of the cross-busses 356 generally have one or more leads that are used to connect the side-buss 355 and the cross-buss 356 to the electrical connections found in a junction box 370, which is used to connect the formed solar cell to the other external electrical components.

In the next step, step 132, a bonding material 360 (FIG. 3D) and “back glass” substrate 361 are prepared for delivery into the solar cell formation process (i.e., process sequence 100). The preparation process is generally performed in the glass lay-up module 232, which generally comprises a material preparation module 232A, a glass loading module 232B, a glass cleaning module 232C, and a glass inspection module 232D. The back glass substrate 361 is bonded onto the device substrate 303 formed in steps 102-131 above by use of a laminating process (step 134 discussed below). In general, step 132 requires the preparation of a polymeric material that is to be placed between the back glass substrate 361 and the deposited layers on the device substrate 303 to form a hermetic seal to prevent the environment from attacking the solar cell during its life. Referring to FIG. 2, step 132 generally comprises a series of sub-steps in which a bonding material 360 is prepared in the material preparation module 232A, the bonding material 360 is then placed over the device substrate 303, and the back glass substrate 361 is loaded into the loading module 232B. The back glass substrate 361 is washed by the cleaning module 232C. The back glass substrate 361 is then inspected by the inspection module 232D, and the back glass substrate 361 is placed over the bonding material 360 and the device substrate 303.

In one embodiment, the material preparation module 232A is adapted to receive the bonding material 360 in a sheet form and perform one or more cutting operations to provide a bonding material, such as Polyvinyl Butyral (PVB) or Ethylene Vinyl Acetate (EVA) that is sized to form a reliable seal between the backside glass and the solar cells formed on the device substrate 303. In general, when using bonding materials 360 that are polymeric, it is desirable to control the temperature (e.g., 16-18° C.) and relative humidity (e.g., RH 20-22%) of the solar cell production line 200 where the bonding material 360 is stored and integrated into the solar cell device to assure that the attributes of the bond formed in the bonding module 234 are repeatable and the dimensions of the polymeric material is stable. It is generally desirable to store the bonding material prior to use in temperature and humidity controlled area (e.g., T=6-8° C.; RH=20-22%). The tolerance stack up of the various components in the bonded device (Step 134) can be an issue when forming large solar cells, therefore accurate control of the bonding material properties and tolerances of the cutting process are required to assure that a reliable hermetic seal is formed. In one embodiment, PVB may be used to advantage due to its UV stability, moisture resistance, thermal cycling, good US fire rating, compliance with Intl Building Code, low cost, and reworkable thermo-plastic properties. In one part of step 132, the bonding material 360 is transported and positioned over the back contact layer 350, the side-buss 355 (FIG. 3C), and the cross-buss 356 (FIG. 3C) elements of the device substrate 303 using an automated robotic device. The device substrate 303 and bonding material 360 are then positioned to receive a back glass substrate 361, which can be placed thereon by use of the same automated robotic device used to position the bonding material 360, or a second automated robotic device.

In one embodiment, prior to positioning the back glass substrate 361 over the bonding material 360, one or more preparation steps are performed to the back glass substrate 361 to assure that subsequent sealing processes and final solar product are desirably formed. In one case, the back glass substrate 361 is received in a “raw” state where the edges, overall size, and/or cleanliness of the substrate 361 are not well controlled. Receiving “raw” substrates reduces the cost to prepare and store substrates prior to forming a solar device and thus reduces the solar cell device cost, facilities costs, and production costs of the finally formed solar cell device. In one embodiment of step 132, the back glass substrate 361 surfaces and edges are prepared in a seaming module (e.g., seamer 204) prior to performing the back glass substrate cleaning step.

In the next sub-step of step 132, the back glass substrate 361 is transported to the cleaning module 232C in which a substrate cleaning step, is performed on the substrate 361 to remove any contaminants found on the surface of the substrate 361. Common contaminants may include materials deposited on the substrate 361 during the substrate forming process (e.g., glass manufacturing process) and/or during shipping of the substrates 361. Typically, the cleaning module 232B uses wet chemical scrubbing and rinsing steps to remove any undesirable contaminants as discussed above.

In the next sub-step of step 132, the back glass substrate 361 is inspected via the inspection module 232D, and metrology data is collected and sent to the system controller 290. In one embodiment, the back glass substrate 361 is optically inspected for defects, such as chips, cracks, or scratches that may inhibit performance of a fully formed solar cell device, such as the solar cell 300.

In one embodiment, the back glass substrate 361 is passed through the inspection module 232D via an automation device 281. As the back glass substrate 361 passes through the inspection module 232D, the back glass substrate 361 is optically inspected, and images of the back glass substrate 361 are captured and sent to the system controller 290, where the images are analyzed and metrology data is collected and stored.

In one embodiment, the images captured by the inspection module 232D are analyzed by the system controller 290 and analyzed to determine whether the back glass substrate 361 meets specified quality criteria. If the specified quality criteria are met, the back glass substrate 361 continues on within the system 200. However, if the specified criteria are not met, actions may be taken to either repair the defect or reject the defective back glass substrate 361. In one embodiment, defects detected in the back glass substrate 361 are mapped and analyzed in a portion of the system controller 290 disposed locally within the inspection module 232D. In this embodiment, the decision to reject a particular back glass substrate 361 may be made locally within the inspection module 232D.

For instance, the system controller 290 may compare information regarding the size of a crack on an edge of a back glass substrate 361 with a specified allowable crack length to determine whether the back glass substrate 361 is acceptable for continued processing in the system 200. In one embodiment, a crack of about 1 mm or smaller is acceptable. Other criteria that the system controller may compare include the size of a chip in the edge of the back glass substrate 361. In one embodiment, a chip of about 5 mm or less is acceptable. In determining whether to allow continued processing or reject each particular back glass substrate 361, the system controller may apply a weighting scheme to the defects mapped in particular regions of the substrate. For instance, defects detected in critical areas, such as edge regions of the back glass substrate 361, may be given significantly greater weighting than defects found in less critical areas.

In one embodiment, the system controller 290 collects and analyzes the metrology data received from the inspection module 232D for use in determining the root cause of recurring defects in the back glass substrate 361 and correct or tune the preceding processes to eliminate the recurring defects. In one embodiment, the system controller 290, either locally or centrally, maps the defects detected in each back glass substrate 361 for use in metrology data analysis.

One embodiment of an optical inspection module, such as the inspection module 232D is subsequently described in more detail in the section entitled, “Optical Inspection Module.”

The prepared back glass substrate 361 is then positioned over the bonding material and partially device substrate 303 by use of an automated robotic device.

Next the device substrate 303, the back glass substrate 361, and the bonding material 360 are transported to the bonding module 234 in which step 134, or lamination steps are performed to bond the backside glass substrate 361 to the device substrate formed in steps 102-132 discussed above. In step 134, a bonding material 360, such as Polyvinyl Butyral (PVB) or Ethylene Vinyl Acetate (EVA), is sandwiched between the backside glass substrate 361 and the device substrate 303. Heat and pressure are applied to the structure to form a bonded and sealed device using various heating elements and other devices found in the bonding module 234. The device substrate 303, the back glass substrate 361 and bonding material 360 thus form a composite solar cell structure 304 (FIG. 3D) that at least partially encapsulates the active regions of the solar cell device. In one embodiment, at least one hole formed in the back glass substrate 361 remains at least partially uncovered by the bonding material 360 to allow portions of the cross-buss 356 or the side buss 355 to remain exposed so that electrical connections can be made to these regions of the solar cell structure 304 in future steps (i.e., step 138).

In one embodiment, the composite solar cell structure 304 may be optionally transferred into another inspection module 206, where a corresponding inspection step 106 may be performed on the composite solar cell structure 304 to detect any damage caused by handling devices within the bonding module 234. In one embodiment, the composite solar cell structure 304 is passed through the inspection module 206 via the automation device 281. In one embodiment of the inspection step 106, as the composite solar cell structure 304 passes through the inspection module 206, the composite solar cell structure 304 is optically inspected, and images of the composite solar cell structure 304 are captured and sent to the system controller 290, where the images are analyzed and metrology data is collected and stored in memory.

In one embodiment, the images captured by the inspection module 206 are analyzed by the system controller 290 to determine whether the composite solar cell structure 304 meets specified quality criteria. If the specified quality criteria are met, the composite solar cell structure 304 continues on its path in the system 200. However, if the specified criteria are not met, actions may be taken to either repair the defect or reject the defective composite solar cell structure 304. In one embodiment, defects detected in the composite solar cell structure 304 are mapped and analyzed in a portion of the system controller 290 disposed locally within the inspection module 206. In this embodiment, the decision to reject a particular composite solar cell structure 304 may be made locally within the inspection module 206.

In one embodiment, the system controller 290 may compare information regarding the size of a crack on an edge of a composite solar cell structure 304 with a specified allowable crack length to determine whether the composite solar cell structure 304 is acceptable for continued processing in the system 200. In one embodiment, a crack of about 1 mm or smaller is acceptable. Other criteria that the system controller may compare include the size of a chip in the edge of the composite solar cell structure 304 or the size of an inclusion or bubble in the composite solar cell structure 304. In one embodiment, a chip of about 5 mm or less may be acceptable, and an inclusion or bubble of less than about 1 mm may be acceptable. In determining whether to allow continued processing or reject each particular composite solar cell structure 304, the system controller may apply a weighting scheme to the defects mapped in particular regions of the substrate. For instance, defects detected in critical areas, such as edge regions of the composite solar cell structure 304, may be given significantly greater weighting than defects found in less critical areas.

In one embodiment, the system controller 290 collects and analyzes the metrology data received from the inspection module 206 for use in determining the root cause of recurring defects in the composite solar cell structure 304 so that it can correct or tune the preceding processes to eliminate the recurring defects. In one embodiment, the system controller 290 locally maps the defects detected in each composite solar cell structure 304 for use in a manual or automated metrology data analysis performed by the user or system controller 290. In one embodiment, the optical characteristics of each device composite solar cell structure 304 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next the composite solar cell structure 304 is transported to the autoclave module 236 in which step 136, or autoclave steps are performed on the composite solar cell structure 304 to remove trapped gasses in the bonded structure and assure that a good bond is formed during step 136. In step 136, a bonded solar cell structure 304 is inserted in the processing region of the autoclave module where heat and high pressure gases are delivered to reduce the amount of trapped gas and improve the properties of the bond between the device substrate 303, back glass substrate, and bonding material 360. The processes performed in the autoclave are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the device substrate 303, back glass substrate 361, and bonding material 360 to a temperature that causes stress relaxation in one or more of the components in the formed solar cell structure 304.

In the next step, or lamination quality inspection step 137, the composite solar cell structure 304 is inspected via an inspection module 237, and metrology data is collected and sent to the system controller 290. In one embodiment, the composite solar cell structure 304 is optically inspected for defects, such as chips, cracks, inclusions, bubbles, or scratches that may inhibit performance of a fully formed solar cell device, such as the solar cell 300.

In one embodiment, the composite solar cell structure 304 is passed through the inspection module 237 by use of an automation device 281. As the composite solar cell structure 304 passes through the inspection module 237, the composite solar cell structure 304 is optically inspected, and images of the composite solar cell structure 304 are captured and sent to the system controller 290, where the images are analyzed and metrology data is collected and stored.

In one embodiment, the images captured by the inspection module 237 are analyzed by the system controller 290 and compared with programmed data to determine whether the composite solar cell structure 304 meets specified quality criteria. If the specified quality criteria are met, the composite solar cell structure 304 continues on its path in the system 200. However, if the specified criteria are not met, actions may be taken to either repair the defect or reject the defective composite solar cell structure 304. In one embodiment, defects detected in the composite solar cell structure 304 are mapped and analyzed in a portion of the system controller 290 disposed locally within the inspection module 232D. In this embodiment, the decision to reject a particular composite solar cell structure 304 may be made locally within the inspection module 232D.

For instance, the system controller 290 may compare information regarding the size of a crack propagated from the edge of the composite solar cell structure 304 with a specified allowable crack length to determine whether the composite solar cell structure 304 is acceptable for continued processing in the system 200. In one embodiment, a crack of about 1 mm or smaller may be acceptable. Other criteria that the system controller may compare include the size of a chip in the edge of the composite solar cell structure 304 or the size of an inclusion or bubble in the composite solar cell structure 304. In one embodiment, a chip of about 5 mm or less is acceptable, and an inclusion or bubble of about 1 mm is acceptable. In determining whether to allow continued processing or reject each particular composite solar cell structure 304, the system controller may apply a weighting scheme to the defects mapped in particular regions of the composite solar cell structure 304. For instance, defects detected in critical areas, such as edge regions of the composite solar cell structure 304, may be given significantly greater weighting than defects found in less critical areas.

In one embodiment, the system controller 290 collects and analyzes the metrology data received from the inspection module 237 for use in determining the root cause of recurring defects in the composite solar cell structure 304 and correct or tune the preceding processes, such as the autoclave step 136, to eliminate the recurring defects. In one embodiment, the system controller 290 maps the defects detected in each composite solar cell structure 304, either locally or centrally, for use in metrology data analysis. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

One embodiment of an optical inspection module, such as the inspection module 237 is subsequently described in more detail in the section entitled, “Optical Inspection Module.”

Next the solar cell structure 304 is transported to the junction box attachment module 238 in which junction box attachment steps 138 are performed on the formed solar cell structure 304. The junction box attachment module 238, used during step 138, is used to install a junction box 370 (FIG. 3C) on a partially formed solar cell. The installed junction box 370 acts as an interface between the external electrical components that will connect to the formed solar cell, such as other solar cells or a power grid, and the internal electrical connections points, such as the leads, formed during step 131. In one embodiment, the junction box 370 contains one or more connection points 371, 372 so that the formed solar cell can be easily and systematically connected to other external devices to deliver the generated electrical power.

In one embodiment, the composite solar cell structure 304 may be optionally transferred into another inspection module 206, where a corresponding inspection step 106 may be performed on the composite solar cell structure 304 to detect any damage caused by handling devices within the junction box attachment module 238. In one embodiment, the composite solar cell structure 304 is passed through the inspection module 206 via the automation device 281. In one embodiment of the inspection step 106, as the composite solar cell structure 304 passes through the inspection module 206, the composite solar cell structure 304 is optically inspected, and images of the composite solar cell structure 304 are captured and sent to the system controller 290, where the images are analyzed and metrology data is collected and stored in memory.

In one embodiment, the images captured by the inspection module 206 are analyzed by the system controller 290 to determine whether the composite solar cell structure 304 meets specified quality criteria. If the specified quality criteria are met, the composite solar cell structure 304 continues on its path in the system 200. However, if the specified criteria are not met, actions may be taken to either repair the defect or reject the defective composite solar cell structure 304. In one embodiment, defects detected in the composite solar cell structure 304 are mapped and analyzed in a portion of the system controller 290 disposed locally within the inspection module 206. In this embodiment, the decision to reject a particular composite solar cell structure 304 may be made locally within the inspection module 206.

In one embodiment, the system controller 290 may compare information regarding the size of a crack on an edge of a composite solar cell structure 304 with a specified allowable crack length to determine whether the composite solar cell structure 304 is acceptable for continued processing in the system 200. In one embodiment, a crack of about 1 mm or smaller is acceptable. Other criteria that the system controller may compare include the size of a chip in the edge of the composite solar cell structure 304 or the size of an inclusion or bubble in the composite solar cell structure 304. In one embodiment, a chip of about 5 mm or less may be acceptable, and an inclusion or bubble of less than about 1 mm may be acceptable. In determining whether to allow continued processing or reject each particular composite solar cell structure 304, the system controller may apply a weighting scheme to the defects mapped in particular regions of the substrate. For instance, defects detected in critical areas, such as edge regions of the composite solar cell structure 304, may be given significantly greater weighting than defects found in less critical areas.

In one embodiment, the system controller 290 collects and analyzes the metrology data received from the inspection module 206 for use in determining the root cause of recurring defects in the composite solar cell structure 304 so that it can correct or tune the preceding processes to eliminate the recurring defects. In one embodiment, the system controller 290 locally maps the defects detected in each composite solar cell structure 304 for use in a manual or automated metrology data analysis performed by the user or system controller 290. In one embodiment, the optical characteristics of each device composite solar cell structure 304 are compared with downstream metrology data in order to correlate and diagnose trends in the production line 200. In one embodiment, a user or the system controller 290 make take corrective action based on the metrology data collected and analyzed, such as altering process parameters in one or more of the processes or modules in the production line 200. In another embodiment, the system controller 290 uses the metrology data to identify malfunctioning downstream modules. The system controller 290 may then take corrective action, such as taking the malfunctioning module offline and reconfiguring the manufacturing process flow around the malfunctioning process module.

Next the solar cell structure 304 is transported to the device testing module 240 in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells. In step 140, a light emitting source and probing device are used to measure the output of the formed solar cell device by use of one or more automated components that are adapted to make electrical contact with terminals in the junction box 370. If the module detects a defect in the formed device it can take corrective actions or the solar cell can be scrapped.

Next the solar cell structure 304 is transported to the support structure module 241 in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site.

Next the solar cell structure 304 is transported to the unload module 242 in which step 142, or device unload steps are performed on the substrate to remove the formed solar cells from the solar cell production line 200.

In one embodiment of the solar cell production line 200, one or more regions in the production line are positioned in a clean room environment to reduce or prevent contamination from affecting the solar cell device yield and useable lifetime. In one embodiment, as shown in FIG. 2, a class 10,000 clean room space 250 is placed around the modules used to perform steps 108-118 and steps 130-134.

### Optical Inspection Module

FIG. 4 is a schematic, isometric view of an optical inspection module 400, such as the inspection modules 206, 214, 229, 232D, and 237. In one embodiment, the optical inspection module 400 comprises a frame structure 405, an illumination source 415, and an optical inspection device 420. In one embodiment, the illumination source 415 includes a uniform line source for projecting a line of light across the width of the substrate 302, 303. The illumination source 415 may comprise any type of light source capable of illuminating the substrate 302, 303 for inspection thereof. In one embodiment, the wavelength of light emitted from the illumination source 415 may be controlled to provide optimum optical inspection conditions. In one embodiment, the illumination source 415 may emit only wavelengths of light in the red spectrum. In one embodiment, the illumination source 415 may emit wavelengths of light in the red spectrum followed by wavelengths of light in the blue spectrum.

In one embodiment, the optical inspection device 420 comprises one or more cameras, such as CCD cameras, and other supporting components that are used to optically inspect various regions of the substrate 302, 303. In one embodiment, the optical inspection device 420 comprises a plurality of CCD cameras positioned above the illumination source 415, such that the substrate 302, 303 may be translated between the optical inspection device 420 and the illumination source 415. In one embodiment, the optical inspection device 420 is in communication with the system controller 290.

In one embodiment, the optical inspection module 400 is positioned within the system 200 to receive a substrate 302, 303 from the automation device 281. The automation device 281 may feed the substrate 302, 303 between the optical inspection device 420 and the illumination source 415 as the substrate 302, 303 is translated through the optical inspection module 400. In one embodiment, as the substrate 302, 303 is fed through the optical inspection module 400, the substrate 302, 303 is illuminated from one side of the substrate 302, 303 via the illumination source 415, while the optical inspection device 420 captures images from the opposite side of the substrate 302, 303. The optical inspection device 420 sends the captured images of the substrate 302, 303 to the system controller 290, where the images are analyzed and metrology data is collected. In one embodiment, the images are retained by portions of the central controller 290 disposed locally within the optical inspection module 400 for analysis. In one embodiment, the system controller 290 uses the information supplied by the optical inspection device 420 to determine whether the substrate 302, 303 meets specified criteria. The system controller 290 may then take specific action to correct any defects detected or reject the substrate 302, 303 from the system 200. In one embodiment, the system controller 290 may use the information collected from the optical inspection device 420 to diagnose the root cause of a recurring defect and correct or tune the process to minimize or eliminate the recurrence of the defect.

### Control System Design

Embodiments of the present invention may also provide an automation system that contains one or more controllers that are able to control the flow of substrates, materials, and the allocation of processing chambers within the solar cell fabrication process sequence. The automation system may also be used to control and tailor the properties of each completed device formed in the system in real time. The automation system may also be used to control the startup and troubleshooting of the system to reduce substrate scrap, improve device yield, and improve the time to produce a substrate.

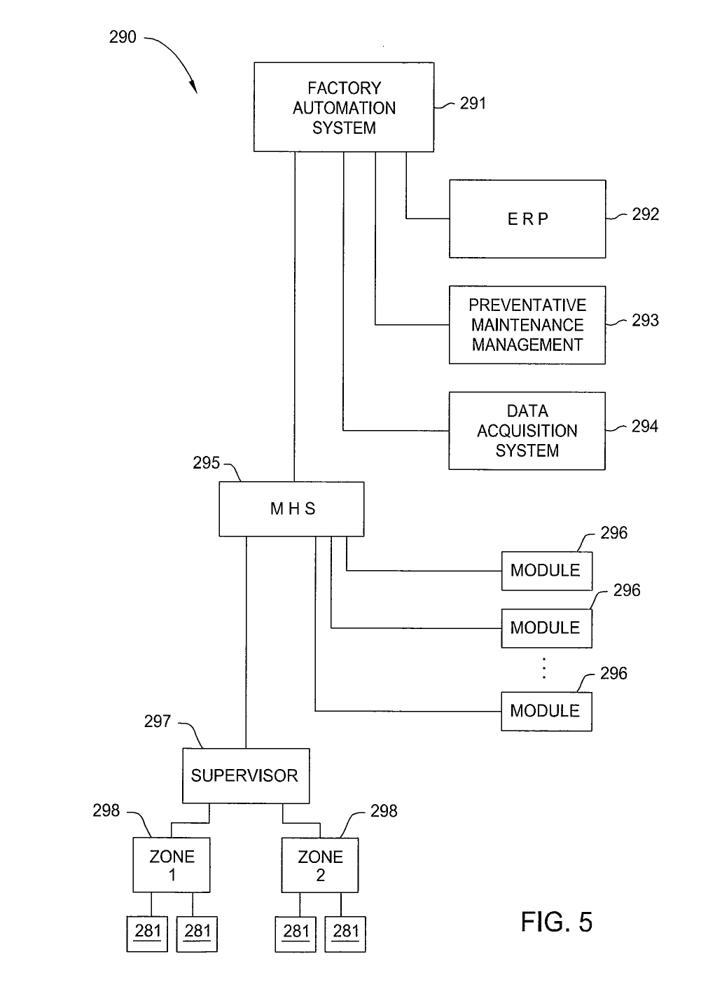

FIG. 5 is a schematic view of one embodiment of the various control features that may be contained within the system controller 290. In one embodiment, the system controller 290 contains a factory automation system (FAS) 291 that deals with the strategic aspects of the substrate processing, and thus may control the dispatch of substrates into or through various parts of the system and the scheduling of various maintenance activities. The FAS thus is able to control and receive information from a number of components in the control architecture, such as a material handling/control system (MHS) 295, an enterprise resource (ERP) system 292, a preventive maintenance (PM) management system 293, and a data acquisition system 294. The FAS 291 generally provides complete control and monitoring of the factory, the use of feedback control, feed forward control, automatic process control (APC), and statistic process control (SPC) techniques, along with the other continuous improvement techniques to improve factory yield. The FAS 291 may further comprise other control systems, such as a yield management system (YMS), to facilitate analysis of metrology data and diagnosis of malfunctioning modules within particular solar cell fabrication routing sequences in the production line 200.

The MHS system 295 generally controls the actual movement and interface of various modules within the system to control the movement of one or more substrates through the system. The MHS system 295 generally interfaces with multiple programmable logic controllers (PLCs) that each tasked with the movement and control of various smaller aspects of processing performed in the solar cell production line 200. The MHS and FAS systems may use feed forward or other automation control logic to control and deal with the systematic movement of substrates through the system. Since cost to manufacture solar cells is generally an issue, minimizing the capital cost of the production line is often an important issue that needs to be addressed. Therefore, in one embodiment, the MHS system 295 utilizes a network of inexpensive programmable logic controllers (PLCs) to perform the lower level control tasks, such as controlling the one or more of the automated devices 281, and controlling the one or more of the modules 296 (e.g., junction box attachment module 238, autoclave module 236) contained in the production line 200. Use of this configuration of devices also has an advantage since PLCs are generally very reliable and easy to upgrade. In one example, the MHS system 295 is adapted to control the movement of substrates through groups, or zones 298, of automated devices 281 by use of commands sent from the MHS system and delivered through supervisor controller 297, which may also be a PLC type device.

The ERP system 292 deals with the various financial and support type functions that arise during the production of solar cell devices. The ERP system 292 can be used to ensure that the each module is available for use at a desired time within the production sequence. The ERP system 292 may control and advise the users of various current and upcoming support type issues in the production line. In one embodiment, the ERP system 292 has the capability to predict and order the various consumable materials used within the production sequence. The ERP system 292 may also be used to review, analyze and control the throughput of the system to improve profit margins on the formed devices. In one embodiment the ERP system 292 is integrated with SAP to order and control of the management of consumable materials, spares, and other material related issues.

The (PM) management system 293 is generally used to control the scheduling and taking down of various elements in the system to perform maintenance activities. The PM management system 293 can thus be used to coordinate the maintenance activities being performed on adjacent modules in the production line to assure that down time of the production line, or branch of the production line, can be minimized. In one example, it may be desirable to take down cluster tool 212B and its associated inlet automation device 281 to reduce the unnecessary down time of both parts when either component separately removed from service. The PM management system 293 and ERP system 292 can generally work together to assure that all of the spare parts and other consumable elements have been ordered and are waiting for the maintenance staff when the preventive maintenance activity is ready to be performed.

In one embodiment, the FAS 291 is also coupled to a data acquisition system 294 that is adapted receive, store, analyze and report various process data received from each of the processing tools, in-line metrology data, offline metrology data and other indicators that are useful to assure that the processes being performed on the substrates are repeatable and within specification. The input and output data that is collected from internal inputs/sensors or from external sources (e.g., external systems (ERP, remote source)) is analyzed and distributed to desired areas of the solar cell production line and/or is integrated in various areas of the process sequence to improve the cycle time, system or chamber availability, device yield and efficiency of the process. One embodiment, provides the use of factory automation software for the control of a photovoltaic cell manufacturing facility. The factory automation software provides work in progress (WIP) data storage and analysis as well as serial number tracking and data storage. The software also performs data mining to improve yield and link with the company ERP to assist in forecasting, WIP planning, sales, warranty claim payment and defense, and cash flow analysis.

While the foregoing is directed to embodiments of the present invention, other and further embodiments of the invention may be devised without departing from the basic scope thereof, and the scope thereof is determined by the claims that follow.

1. A solar cell production line, comprising:
a plurality of automation devices configured to serially transfer substrates along a path;
a first optical inspection module positioned along the path to receive a substrate having a front contact layer deposited thereon and positioned upstream from one or more cluster tools having at least one processing chamber adapted to deposit a silicon-containing layer on a surface of the substrate, wherein the optical inspection module comprises an inspection device that is positioned to view a region of the substrate and is configured to optically receive information regarding whether defects are present in the viewed region;
a film characterization module positioned along the path downstream from the one or more cluster tools and having one or more inspection devices configured to inspect a region of the silicon-containing layer disposed on the surface of the substrate such that information regarding the thickness of the silicon-containing layer can be determined; and
a system controller assembly in communication with each of the modules and configured to analyze information received from each of the modules and issue instructions for taking corrective actions to one or more of the modules within the production line.

2. The solar cell production line of claim 1, wherein the first optical inspection module comprises an illumination source and a plurality of inspection devices, and wherein the inspection devices are each configured to capture optical images of regions of the substrate as the substrate is positioned between the illumination source and the plurality of inspection devices.

3. The solar cell production line of claim 2, wherein the film characterization module comprises:
an automation device configured to laterally move the substrate through the film characterization module;
an illumination source positioned to illuminate one side of the substrate; and
an inspection device positioned to spectrographically inspect the region of the silicon-containing layer and detect the positioning and velocity of the substrate as the automation device transfers the substrate through the film-characterization module.

4. The solar cell production line of claim 3, further comprising:
a second optical inspection module positioned along the path downstream from the one or more cluster tools and having one or more illumination sources and an inspection device that is positioned to serially illuminate a region of the substrate with separate non-overlapping wavelengths of light while viewing the region of the substrate, wherein the second optical inspection module is configured to optically receive information regarding whether a defect in the one or more of silicon-containing layers is present in the viewed region.

5. The solar cell production line of claim 4, wherein the system controller is further configured to issue instructions to reject the substrate if the information received from the first optical inspection module indicates that defects present in the viewed region exceed a threshold value and to issue instructions to the at least one processing chamber to alter a processing parameter based on the information regarding the thickness of the silicon-containing layer and whether a defect is present in the one or more silicon-containing layers.

6. The solar cell production line of claim 5, further comprising:
a back contact layer inspection module positioned along the path downstream from the one or more cluster tools to receive the substrate having a back contact layer formed over the one or more silicon-containing layers and having a plurality of electrical probes, a light source, a measurement device, and one or more sensors and is configured to measure electrical and optical properties of the back contact layer;
a quality assurance module positioned along the path downstream from the one or more cluster tools to receive the substrate having the back contact layer deposited over the silicon-containing layer, wherein at least a portion of the front contact layer, the silicon-containing layer, and the back contact layer are removed to form at least two serially connected solar cells, wherein the quality assurance module has a plurality of probes and a measurement device coupled to at least two of the plurality of probes configured to measure at least one electrical property of the at least two serially connected solar cells.

7. A solar cell production line, comprising:
a first optical inspection module positioned within the production line upstream from one or more cluster tools having one or more processing chambers adapted to deposit a plurality of silicon-containing layers over the front contact layer and configured to receive a substrate having a front contact layer deposited thereon, wherein the first optical inspection module comprises an inspection device that is positioned to view a region of the substrate and is configured to optically receive information regarding whether defects are present in the viewed region;
a second optical inspection module positioned downstream from the one or more cluster tools and configured to receive the substrate having the plurality of silicon-containing layers deposited thereon, wherein the second optical inspection module comprises an inspection device that is positioned to view a region of the substrate and is configured to optically receive information regarding whether a defect in the plurality of silicon-containing layers is present in the viewed region;
a plurality of scribe inspection modules, wherein a first of the plurality of scribe inspection modules is positioned downstream from the second optical inspection module and configured to receive the substrate having a plurality of scribed regions formed in the plurality of silicon-containing layers, wherein the first scribe inspection module is configured to optically inspect the scribed regions formed in the plurality of silicon-containing layers; and
a system controller assembly in communication with each of the modules and configured to analyze information received from each of the modules and issue instructions for taking corrective actions to one or more of the modules within the production line.

8. The solar cell production line of claim 7, further comprising:
an electrical inspection module positioned within the production line upstream from the one or more cluster tools to receive the substrate having a plurality of isolation regions formed in the front contact layer, wherein the electrical inspection module has a plurality of probes and a measuring device configured to measure electrical continuity across the isolation regions; and
a back contact layer inspection module positioned downstream from the first of the plurality of scribe inspection modules and configured to receive the substrate having a back contact layer formed over the plurality of silicon-containing layers, wherein the back contact layer inspection module is configured to measure electrical and optical properties of the back contact layer.

9. The solar cell production line of claim 8, wherein a second of the plurality of scribe inspection modules is positioned downstream from the first of the plurality of scribe inspection modules to receive the substrate having a plurality of scribed regions formed in the back contact layer deposited over the plurality of silicon-containing layers and optically inspect the scribed regions formed in the back contact layer.

10. The solar cell production line of claim 9, further comprising a third optical inspection module positioned downstream from the second of the plurality of scribe inspection modules and having an illumination source positioned to illuminate a region of the substrate and an inspection device positioned to view the region of the substrate and optically receive information regarding whether defects are present in the viewed region.

11. The solar cell production line of claim 10, further comprising a quality assurance module positioned downstream from the second of the plurality of scribe inspection modules to receive the substrate having the plurality of scribed regions formed in the back contact layer deposited over the plurality of silicon-containing layers and has a plurality of probes and a measurement device coupled to the plurality of probes configured to measure at least one electrical property across the scribed regions formed in the back contact layer.

12. The solar cell production line of claim 11, further comprising a fourth optical inspection module disposed within a back glass lay-up module positioned downstream from the quality assurance module and positioned to inspect a back glass substrate prior to placing the back glass substrate over the metal-containing layer to form a composite structure.

13. The solar cell production line of claim 12, further comprising a fifth optical inspection module positioned downstream from the fourth optical inspection module and configured to optically inspect the composite structure.

14. A method of forming solar cells in a production line, comprising:
serially transferring a plurality of substrates along a transfer path using a plurality of automation devices;
processing each of the plurality of substrates in a plurality of processing modules disposed along the transfer path, wherein processing each of the plurality of substrates comprises:
removing a portion of a front contact layer deposited on a surface of each substrate in a first processing module positioned along the transfer path;
depositing a first plurality of silicon-containing layers over the front contact layer in a first cluster tool within a second processing module positioned downstream from the first processing module along the transfer path;
removing a portion of the plurality of silicon-containing layers in a third processing module positioned downstream from the second processing module along the transfer path;
depositing a metal layer over the plurality of silicon-containing layers in a fourth processing module positioned downstream from the third processing module along the transfer path; and
removing a portion of the metal layer in a fifth processing module positioned downstream from the fourth processing module to form at least two serially connected solar cells on each substrate; and
inspecting each of the plurality of substrates in a plurality of inspection modules which are disposed along the transfer path, wherein inspecting each of the plurality of substrates comprises:
optically inspecting a region of each substrate in a first inspection module positioned upstream from the second processing module and determining whether a defect exists within the region;
measuring electrical continuity between portions of the front contact layer disposed on opposite sides of the removed portion of the front contact layer in a second inspection module positioned upstream from the second processing module;
inspecting the first plurality of silicon-containing layers on each substrate in a third inspection module positioned downstream from the first cluster tool and determining the thickness of at least one of the first plurality of silicon-containing layers;
optically inspecting a region of at least the first plurality of silicon-containing layers of each substrate in a fourth inspection module positioned downstream from the second processing module and determining whether a defect exists in the plurality of silicon-containing layers within the region;
optically inspecting a region of each substrate where at least a portion of at least the first plurality of silicon-containing layers has been removed in a fifth inspection module positioned downstream from the third processing module; and
optically inspecting a region of each substrate where at least a portion of the metal layer has been removed in a sixth inspection module positioned downstream from the fifth processing module.

15. The method of claim 14, further comprising:
depositing a second plurality of silicon-containing layers over the first plurality of silicon-containing layers in a second cluster tool within the second processing module; and
inspecting the second plurality of silicon-containing layers in a seventh inspection module positioned along the transfer path downstream from the second cluster tool and determining the thickness of at least one of the second plurality of silicon-containing layers.

16. The method of claim 14, further comprising measuring at least one electrical property of the at least two serially connected solar cells on each substrate in an eighth inspection module positioned along the path downstream from the sixth inspection module and determining whether a defect exists in the at least two serially connected solar cells on each substrate.

17. A solar cell production line, comprising:
a plurality of automation devices which are configured to serially transfer substrates along a path;
a first scribe module positioned along the path to receive a substrate having a front contact layer deposited thereon and configured to form a plurality of scribed regions in the front contact layer;
a first cluster tool positioned along the path downstream from the first scribe module and having one or more processing chambers configured to deposit a first plurality of silicon-containing layers over the front contact layer;
a first film characterization module positioned along the path downstream from the first cluster tool and having one or more inspection devices configured to inspect a region of the first silicon-containing layers disposed on the surface of each substrate such that information regarding the thickness of at least one of the first plurality of silicon-containing layers can be determined;
a second cluster tool positioned along the path downstream from the first film characterization module and having one or more processing chambers configured to deposit a second plurality of silicon-containing layers over the first plurality of silicon-containing layers;
a second film characterization module positioned along the path downstream from the second cluster tool and having one or more inspection devices configured to inspect a region of the second silicon-containing layers disposed on the surface of each substrate such that information regarding the thickness of at least one of the second plurality of silicon-containing layers can be determined; and
a system controller assembly in communication with the first and second film characterization modules and configured to analyze information received from each of the first and second film characterization modules and issue instructions for taking corrective actions to one or more of the modules within the production line.

18. The solar cell production line of claim 17, further comprising a plurality of optical inspection modules positioned along the path, comprising:
a first optical inspection module positioned upstream from the first cluster tool and having an inspection device that is positioned to view a region of the substrate and optically receive information regarding whether defects are present in the viewed region; and
a second optical inspection module positioned along the path downstream from the second cluster tool and having an illumination source positioned to illuminate a region of the first and second plurality of silicon-containing layers and an inspection device configured to view the illuminated region and optically receive information regarding whether defects are present in the first and second plurality of silicon-containing layers in the viewed region.

19. The solar cell production line of claim 18, further comprising:
a second scribe module positioned along the path downstream from the second cluster tool and configured to form a plurality of scribed regions in the first and second plurality of silicon-containing layers;
a first scribe inspection module positioned along the path downstream from the second scribe module and configured to optically inspect the plurality of scribed regions in the first and second plurality of silicon-containing layers;
a deposition module positioned downstream from the first scribe module and configured to deposit a metal-containing layer over the first and second plurality of silicon-containing layers; and
a second scribe module positioned along the path downstream from the deposition module and configured to form a plurality of scribed regions in the metal-containing layer; and
a second scribe inspection module positioned along the path downstream from the second scribe module and configured to optically inspect the plurality of scribed regions in the metal-containing layer.

20. The solar cell production line of claim 19, further comprising a quality assurance module positioned along the path downstream from the second scribe module and having a light source positioned to illuminate the substrate, a plurality of probes positioned to contact the metal-containing layer on opposite sides of each of the plurality of scribed regions in the metal-containing layer, and a measurement device coupled to the plurality of probes configured to measure at least one electrical property of a region of the substrate.
